(19) United States
(12) Patent Application Publication
(10) Pub. No.: US 2024/0260256 A1
(43) Pub. Date: Aug. 1, 2024

(54) SEMICONDUCTOR DEVICES AND MANUFACTURING METHODS FOR THE SAME

(71) Applicant: SAMSUNG ELECTRONICS CO., LTD., Suwon-si (KR)

(72) Inventors: Taeyoung EOM, Suwon si (KR); Sunghoon Bae, Suwon si (KR); Halim Noh, Suwon si (KR); Heecheol Shin, Suwon si (KR)

(21) Appl. No.: 18/424,919

(22) Filed: Jan. 29, 2024

(30) Foreign Application Priority Data
Jan. 30, 2023 (KR) 10-2023-0011858

(51) Int. Cl. H10B 12/00

(52) U.S. Cl. CPC H10B 12/482; H10B 12/033; H10B 12/315; H10B 12/50

(57) ABSTRACT

A semiconductor device includes a substrate having an active region defined by a device separation layer, a plurality of bit lines on the substrate, a buried contact disposed on the substrate between adjacent bit lines among the plurality of bit lines and connected to the active region, an intermediate conductive layer disposed on the buried contact, a landing pad disposed on the intermediate conductive layer, and an insulating pattern on a sidewall of the landing pad and contacting at least a portion of a top surface of the intermediate conductive layer.

### CROSS-REFERENCE TO RELATED APPLICATION

This application is based on and claims priority under 35 U.S.C. § 119 to Korean Patent Application No. 10-2023-0011858, filed on Jan. 30, 2023, in the Korean Intellectual Property Office, the disclosure of which is incorporated by reference herein in its entirety.

### TECHNICAL FIELD

The inventive concept relates to a semiconductor device and a method of manufacturing the same, and more particularly, to a semiconductor device including bit lines and a method of manufacturing the same.

### DESCRIPTION OF RELATED ART

The performance of semiconductor devices may be improved by reducing the size of individual circuit patterns for implementing the semiconductor devices. In addition, as a degree of integration of the semiconductor devices in an integrated circuit increases, a line width of bit lines becomes smaller. The potential for defects, such as bridge defects and short circuits, may increase with reduced size and increased integration. In particular, processes for forming contacts between the bit lines may become more difficult to perform.

### SUMMARY

The inventive concept provides an improved method for manufacturing a semiconductor device including contacts between bit lines.

According to an aspect of the inventive concept, a semiconductor device includes a substrate having an active region defined by a device separation layer, a plurality of bit lines disposed on the substrate, a buried contact disposed on the substrate between adjacent bit lines among the plurality of bit lines and connected to the active region, an intermediate conductive layer disposed on the buried contact, a landing pad disposed on the intermediate conductive layer, and an insulating pattern disposed on a sidewall of the landing pad and contacting at least a portion of a top surface of the intermediate conductive layer.

According to another aspect of the inventive concept, a semiconductor device includes a substrate having a plurality of active regions defined by a plurality of device separation layers, a plurality of bit lines disposed on the substrate, a plurality of bit line capping layers arranged on the plurality of bit lines, a plurality of buried contacts disposed on the substrate between adjacent bit lines among the plurality of bit lines, extending in a vertical direction, and connected to the plurality of active regions, a plurality of intermediate conductive layers disposed on the plurality of buried contacts, respectively, having bottom surfaces disposed at a level higher than top surfaces of the plurality of bit lines, a plurality of landing pads disposed on the plurality of intermediate conductive layers, and an insulating pattern disposed on a sidewall of each of the plurality of landing pads and contacting at least a portion of a top surface of each of the plurality of intermediate conductive layers.

According to another aspect of the inventive concept, a semiconductor device includes a substrate having a plurality of active regions defined by a plurality of device separation layers, a plurality of bit lines extending in a first horizontal direction on the substrate, a plurality of bit line capping layers disposed on the plurality of bit lines, respectively, a plurality of spacers arranged on sidewalls of the plurality of bit lines, a word line extending in a second horizontal direction in the substrate and perpendicular to the first horizontal direction, a plurality of buried contacts disposed on the substrate between adjacent bit lines among the plurality of bit lines and connected to the plurality of active regions, a plurality of intermediate conductive layers disposed on the plurality of buried contacts, respectively, and including a metal silicide, a plurality of landing pads disposed on the plurality of intermediate conductive layers, an insulating pattern surrounding a sidewall of each of the plurality of landing pads and contacting at least a portion of a top surface of each of the plurality of intermediate conductive layers, a plurality of lower electrodes disposed on the plurality of landing pads, respectively, a capacitor dielectric layer disposed on the insulating pattern and on sidewalls of the plurality of lower electrodes, and an upper electrode disposed on the capacitor dielectric layer.

### BRIEF DESCRIPTION OF THE DRAWINGS

Embodiments will be more clearly understood from the following detailed description taken in conjunction with the accompanying drawings in which:

FIG. 1 is a layout diagram of a semiconductor device according to some embodiments;

FIG. 2 is an enlarged layout diagram of portion II of FIG. 1;

FIG. 3 is a cross-sectional view taken along line A-A′ of FIG. 2;

FIG. 4 is a cross-sectional view taken along line B-B′ of FIG. 2;

FIG. 5 is a cross-sectional view taken along line C-C′ of FIG. 2;

FIG. 6 is an enlarged view of portion CX1 of FIG. 3;

FIG. 7 is a cross-sectional view of a semiconductor device according to some embodiments;

FIG. 8 is an enlarged view of portion CX1 of FIG. 7;

FIG. 9 is a cross-sectional view of a semiconductor device according to some embodiments; and

FIGS. 10A to 21C are cross-sectional views illustrating a method of manufacturing a semiconductor device according to some embodiments in which, FIGS. 10A, 11A, 12A, 13A, 14A, 15A, 16A, 17A, 18A, 19A, 20A, and 21A are cross-sectional views corresponding to section A-A′ of FIG. 2, and FIGS. 10B, 11B, 12B, 13B, 14B, 15B, 16B, 17B, 18B, 19B, 20B, and 21B are cross-sectional views corresponding to section B-B′ of FIG. 2, and FIGS. 10C, 11C, 12C, 13C, 14C, 15C, 16C, 17C, 18C, 19C, 20C, and 21C are cross-sectional views corresponding to section C-C′ of FIG. 2.

### DETAILED DESCRIPTION

Hereinafter, embodiments will be described in detail with reference to the accompanying drawings.

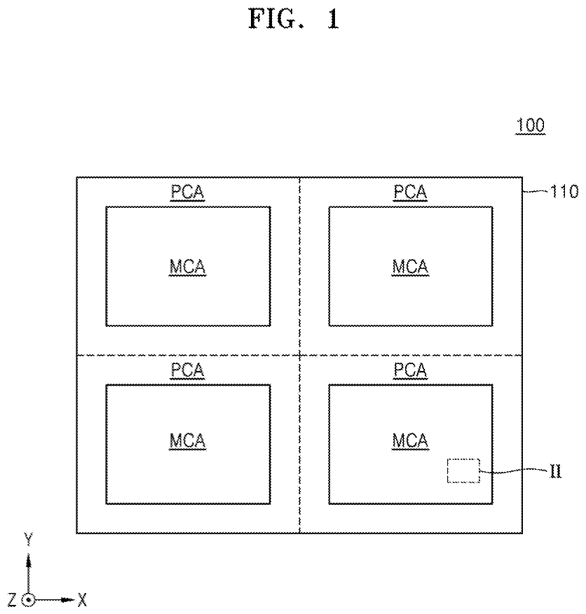

FIG. 1 is a layout diagram of a semiconductor device according to some embodiments.

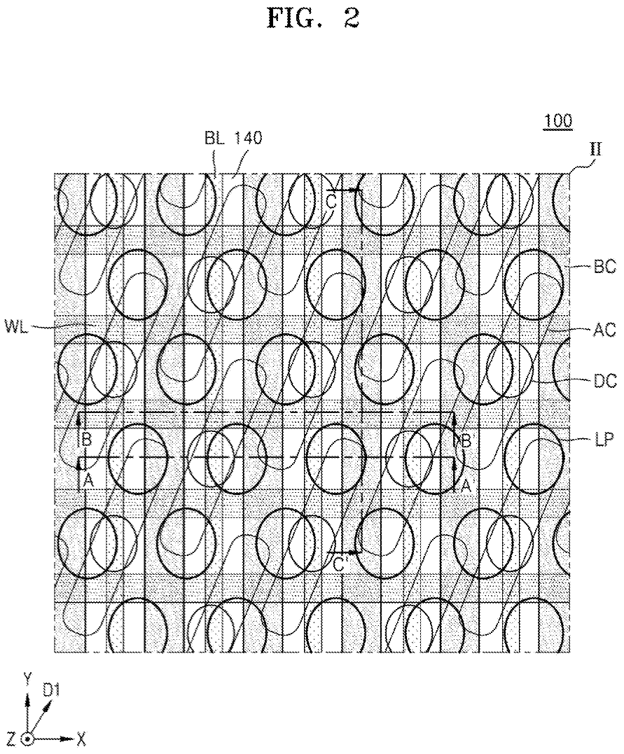

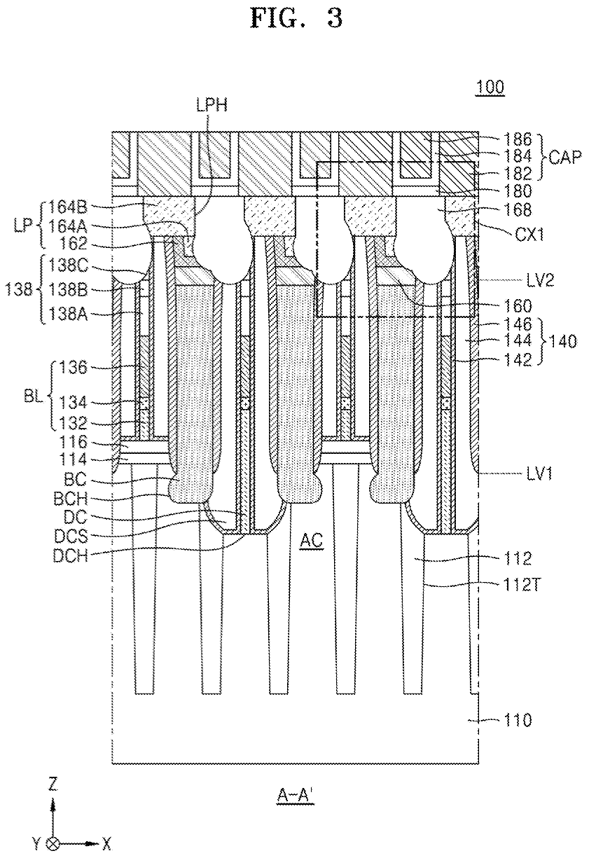

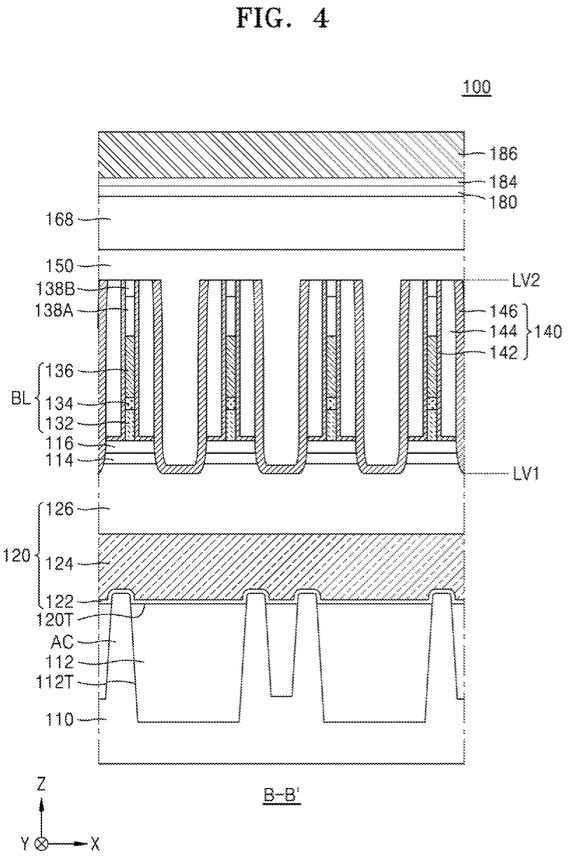

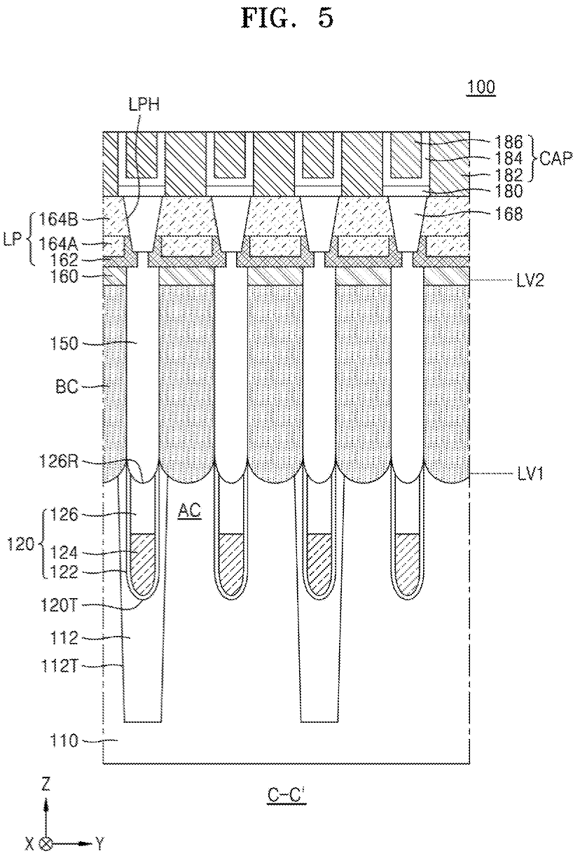

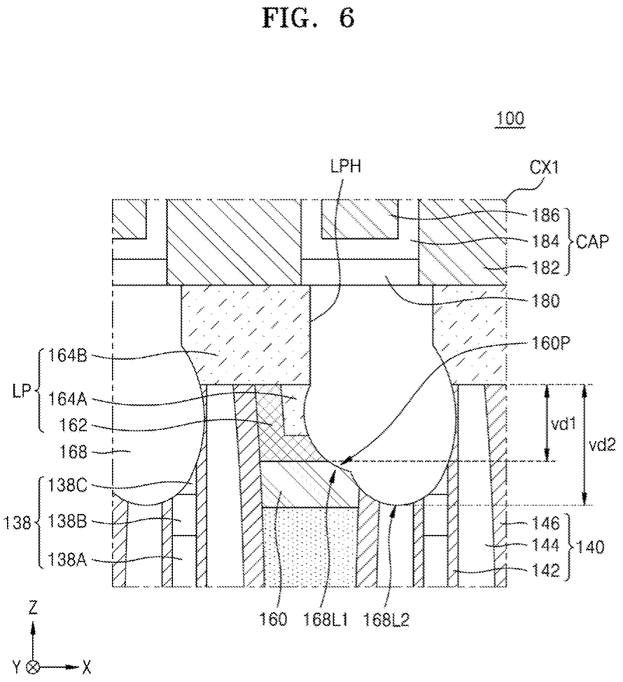

FIG. 2 is an enlarged layout diagram of portion II of FIG. 1. FIG. 3 is a cross-sectional view taken along line A-A′ of FIG. 2. FIG. 4 is a cross-sectional view taken along line B-B′ of FIG. 2. FIG. 5 is a cross-sectional view taken along line C-C′ of FIG. 2. FIG. 6 is an enlarged view of portion CX1 of FIG. 3.

Referring to FIG. 1, FIG. 2, FIG. 3, FIG. 4, FIG. 5, and FIG. 6, the semiconductor device 100 may include a substrate 110 having a cell array area MCA and a peripheral circuit area PCA. The cell array area MCA may be a memory cell area of a DRAM device. The peripheral circuit area PCA may be a core area or a peripheral circuit area of a DRAM device. For example, the cell array area MCA may include a cell transistor and a capacitor structure 180 connected thereto, and the peripheral circuit area PCA may include a peripheral circuit transistor (not shown). The peripheral circuit transistor may transmit signals and/or power to the cell transistor included in the cell array area MCA. In some embodiments, the peripheral circuit transistor may be configured as various circuits. For example, the peripheral circuit transistor may include, a command decoder, control logic, an address buffer, a row decoder, a column decoder, a sense amplifier, a data input/output circuit, or the like.

A device separation trench 112T may be formed in the substrate 110, and a device separation layer 112 may be formed in the device separation trench 112T. A plurality of active regions AC may be defined in the substrate 110 by the device separation layers 112.

FIG. 2 is a plan view of the portion II of FIG. 1. As shown in FIG. 2, each of the plurality of active regions AC may be arranged to have a major axis in a first oblique direction D1 inclined with respect to a first horizontal direction X and a second horizontal direction Y, which may be perpendicular to one another. A plurality of word lines WL may extend parallel to each other in the first horizontal direction X across the plurality of active regions AC. A plurality of bit lines BL may extend parallel to each other in the second horizontal direction Y on the plurality of word lines WL. The plurality of bit lines BL may be connected to the plurality of active regions AC through bit line contacts DC.

A plurality of buried contacts BC may be formed between two adjacent bit lines BL among the plurality of bit lines BL. A plurality of landing pads LP may be formed on the plurality of buried contacts BC. The plurality of buried contacts BC and the plurality of landing pads LP may connect lower electrodes 182 of the capacitor structure CAP formed on the plurality of bit lines BL to the active regions AC. Each of the plurality of landing pads LP may be arranged to partially overlap the buried contacts BC and the bit lines BL.

The substrate 110 may include silicon, for example, monocrystalline silicon, polycrystalline silicon, or amorphous silicon. In some embodiments, the substrate 110 may include at least one selected from Ge, SiGe, SiC, GaAs, InAs, or InP. In some embodiments, the substrate 110 may include a conductive region, for example, a well doped with impurities or a structure doped with impurities.

The device separation layer 112 may include an oxide layer, a nitride layer, or a combination thereof. A first buffer insulating layer 114 and a second buffer insulating layer 116 may be sequentially arranged on a top surface of the substrate 110. For example, the first buffer insulating layer 114 may be deposited directly on the top surface of the substrate 110 and the second buffer insulating layer 116 may be deposited on the first buffer insulating layer 114. Each of the first buffer insulating layer 114 and the second buffer insulating layer 116 may include silicon oxide, silicon oxynitride, or silicon nitride.

A plurality of word line trenches 120T extending in the first horizontal direction X may be arranged on the substrate 110. A buried gate structure 120 may be arranged in the plurality of word line trenches 120T. The buried gate structure 120 may include a gate dielectric layer 122, a gate electrode 124, and a word line capping layer 126 arranged in each of the plurality of word line trenches 120T. The plurality of gate electrodes 124 may correspond to the plurality of word lines WL shown in FIG. 2.

The plurality of gate dielectric layers 122 may include a high-k dielectric film. The plurality of gate dielectric layers 122 may have a higher dielectric constant than a silicon oxide layer, a silicon nitride layer, a silicon oxynitride layer, an oxide/nitride/oxide (ONO) layer, or a silicon oxide layer. The plurality of gate electrodes 124 may include titanium (Ti), titanium nitride (TiN), tantalum (Ta), tantalum nitride (TaN), tungsten (W), tungsten nitride (WN), titanium silicon nitride (TiSiN), tungsten silicon nitride (WSiN), or a combination thereof. The plurality of word line capping layers 126 may include a silicon oxide layer, a silicon nitride layer, a silicon oxynitride layer, or a combination thereof.

A plurality of bit line contact holes DCH may pass through the first buffer insulating layer 114 and the second buffer insulating layer 116 and extend into the substrate 110. The plurality of bit line contacts DC may be formed in the plurality of bit line contact holes DCH. The plurality of bit line contacts DC may be connected to the plurality of active regions AC. The plurality of bit line contacts DC may include TiN, TiSiN, W, tungsten silicide (WSi), doped polysilicon, or a combination thereof. A bit line contact spacer DCS may cover a lower side of the bit line contact DC in the bit line contact hole DCH.

The plurality of bit lines BL may extend in the second horizontal direction Y on the substrate 110 and the plurality of bit line contacts DC. Each of the plurality of bit lines BL may be connected to the active region AC through the bit line contact DC. Each of the plurality of bit lines BL may include a conductive layer 132, an intermediate bit line conductive layer 134, and a bit line conductive layer 136. The intermediate bit line conductive layer 134 may be formed on the conductive layer 132. The bit line conductive layer 136 may be formed on the intermediate bit line conductive layer 134.

In some embodiments, the conductive layer 132 may include polysilicon, and the intermediate bit line conductive layer 134 may include at least one of TiN, TiSiN, cobalt silicide (CoSi), nickel silicide (NiSi), or WSi. The bit line conductive layer 136 may include at least one of ruthenium (Ru), W, Co, Ti, or TiN.

A plurality of bit line capping layers 138 may be arranged on the plurality of bit lines BL, respectively. Each of the bit line capping layers 138 may include a first capping layer 138A, a second capping layer 138B, and a third capping layer 138C sequentially arranged on the plurality of bit lines BL. The first capping layer 138A may be formed on a top surface of the plurality of bit lines BL, the second capping layer 138B may be formed on the first capping layer 138A, and a third capping layer 138C may be formed on the second capping layer 138B. The first capping layer 138A, the second capping layer 138B, and the third capping layer 138C may include at least one of silicon nitride, silicon oxide, or silicon oxynitride.

Spacers 140 may be arranged on sidewalls of each bit line BL. The spacer 140 may include a first spacer layer 142, a second spacer layer 144, and a third spacer layer 146. In some embodiments, the first spacer layer 142 and the third spacer layer 146 may include silicon nitride, and the second spacer layer 144 may include silicon oxide. In some embodiments, the first spacer layer 142 and the third spacer layer 146 may include silicon nitride, and the second spacer layer 144 may include an air space. The first spacer layer 142, the second spacer layer 144, and the third spacer layer 146 may be sequentially arranged on sidewalls of the bit line BL and the bit line capping layer 138. The first spacer layer 142 may be formed directly on the sidewalls of the bit line BL, the second spacer layer 144 may be formed on the first spacer layer 142, and the third spacer layer 146 may be formed on the second spacer layer 144.

The plurality of buried contacts BC may be arranged between the plurality of bit lines BL. For example, bottom portions of the plurality of buried contacts BC may be arranged in buried contact holes BCH. The buried contact holes BCH may extend into the substrate 110 in a vertical direction Z and between adjacent bit lines BL. The buried contact holes BCH may contact the active regions AC. In some embodiments, the plurality of buried contacts BC may include doped polysilicon.

In some embodiments, the plurality of buried contacts BC may have rounded bottom surfaces disposed at a level lower than the top surface of the substrate 110. For example, the bottom surface of the third spacer layer 146 may be disposed at a first vertical level LV1, wherein the first vertical level LV1 may be located at a level lower than the top surface of the substrate 110. Further, a bottom surface of each of the plurality of buried contacts BC may be located at a level lower than the first vertical level LV1. For example, as shown in FIG. 3 and FIG. 5, each of the plurality of buried contacts BC may have a rounded bottom profile in the first horizontal direction X and the second horizontal direction Y.

In some embodiments, the plurality of buried contacts BC may have top surfaces arranged at a level higher than top surfaces of the plurality of bit lines BL. In some embodiments, each of the plurality of buried contacts BC may have a top surface arranged at a level higher than a top surface of the first capping layer 138A and lower than a top surface of the second capping layer 138B. For example, the top surface of the second capping layer 138B may be disposed at a second vertical level LV2, and the top surface of each of the plurality of buried contacts BC may be located at a level lower than the second vertical level LV2.

An insulating fence 150 may extend in the first horizontal direction X. Lower portions of the insulating fence 150 may extend in the vertical direction Z and may be disposed between adjacent bit lines BL. The insulating fence 150 may vertically overlap the plurality of word line trenches 120T. An upper surface of the insulating fence 150 may extend in the first horizontal direction X, and the lower portions of the insulating fence 150 may be spaced apart from adjacent bit lines BL in the first horizontal direction X. From a plan view, the plurality of buried contacts BC and the lower portions of the insulating fence 150 may be alternately arranged between the bit lines BL, where the bit lines BL may extend in the second horizontal direction Y.

A plurality of intermediate conductive layers 160 may be arranged on the plurality of buried contacts BC. The plurality of intermediate conductive layers 160 may include a metal silicide. For example, the plurality of intermediate conductive layers 160 may include at least one of CoSi, NiSi, or WSi. A top surface of each of the plurality of intermediate conductive layers 160 may be arranged at a level higher than the top surface of the second capping layer 138B. The top surface of each of the plurality of intermediate conductive layers 160 may be arranged at a level higher than the second vertical level LV2. For example, the top surface of each of the plurality of intermediate conductive layers 160 may be spaced apart from a top surface of the bit line capping layer 138 in the vertical direction Z by a first vertical distance vd1. The first vertical distance vd1 may range from about 5 to 50 nanometers (nm).

The plurality of landing pads LP may be arranged on the plurality of intermediate conductive layers 160. Each of the plurality of landing pads LP may include a landing pad barrier 162, a first landing pad conductive layer 164A, and a second landing pad conductive layer 164B. The landing pad barrier 162 may be formed on an intermediate conductive layer of the plurality of intermediate conductive layers 160, the first landing pad conductive layer 164A may be formed on the landing pad barrier 162, and the second landing pad conductive layer 164B may be formed on the landing pad barrier 162 and the first landing pad conductive layer 164A. The landing pad barrier 162 may include Ti, TiN, or a combination thereof. The first landing pad conductive layer 164A and the second landing pad conductive layer 164B may include metal, metal nitride, conductive polysilicon, or a combination thereof. For example, the first landing pad conductive layer 164A and the second landing pad conductive layer 164B may include W. The plurality of landing pads LP may have a shape of a plurality of island-shaped patterns when viewed from a plan view.

In some embodiments, the first landing pad conductive layer 164A may have a top surface disposed at the same level as the top surface of the bit line capping layer 138 and the top surface of the insulating fence 150. The second landing pad conductive layer 164B may be disposed on the top surface of the first landing pad conductive layer 164A, the top surface of the bit line capping layer 138, and the top surface of the insulating fence 150. The landing pad barrier 162 may be positioned between the first landing pad conductive layer 164A and the intermediate conductive layer 160 and between the first landing pad conductive layer 164A and the sidewall of the spacer 140. The landing pad barrier 162 may not be positioned between the second landing pad conductive layer 164B and the top surface of the spacer 140, and the second landing pad conductive layer 164B may contact the top surface of the spacer 140.

The plurality of landing pads LP may be electrically insulated from each other by an insulating pattern 168 surrounding the plurality of landing pads LP. The insulating pattern 168 may be disposed in a landing pad hole LPH. The landing pad hole LPH may refer to a space formed by removing portions of the landing pad barrier 162, the first landing pad conductive layer 164A, and the second landing pad conductive layer 164B, and portions of the bit line capping layer 138 and the spacer 140. The landing pad hole LPH may expose the top surface of the intermediate conductive layer 160. The insulating pattern 168, disposed in the landing pad hole LPH, may contact at least a portion of the top surface of the intermediate conductive layer 160. In some embodiments, the insulating pattern 168 may have a first bottom surface 168L1 and a second bottom surface 168L2, wherein the first bottom surface 168L1 may contact the top surface of the intermediate conductive layer 160, and the second bottom surface 168L2 may contact the top surface of the spacer 140 and the top surface of the bit line capping layer 138. For example, the second bottom surface 168L2 may be arranged at a level lower than the first bottom surface 168L1. As shown, the second bottom surface 168L2 may be a lowermost surface of the insulating pattern 168. The insulating pattern 168 may include at least one of silicon nitride, silicon oxide, or silicon oxynitride.

In some embodiments, the lowermost surface (e.g., second bottom surface 168L2) of the insulating pattern 168 may be arranged at a second vertical distance vd2 from the top surface of the bit line capping layer 138. In some embodiments, the second vertical distance vd2 may range from about 5 to 30 nm. In some embodiments, the second vertical distance vd2 may range from about 10 to 20 nm.

The intermediate conductive layer 160 may contact a top surface of the buried contact BC. For example, the intermediate conductive layer 160 may cover an entirety of the top surface of the buried contact BC. A first portion of a top surface of the intermediate conductive layer 160 may be covered by the landing pad LP and a second portion of the top surface of the intermediate conductive layer 160 may be covered by the insulating pattern 168. The first portion of the top surface of the intermediate conductive layer 160 may have a flat profile portion, and the second portion of the top surface of the intermediate conductive layer 160 may include a shoulder portion 160P. The second portion of the top surface of the intermediate conductive layer 160 may be disposed at a level lower than the first portion of the top surface of the intermediate conductive layer 160.

The capacitor structure CAP may be disposed on the plurality of landing pads LP. The capacitor structure CAP may include a lower electrode 182, a capacitor dielectric layer 184, and an upper electrode 186. In some embodiments, a memory element such as a magnetic tunnel junction, a phase change memory element, or a variable resistance memory element may be disposed on the plurality of landing pads. For example, the capacitor structure CAP may be replaced by a memory element.

The buried contact BC may be formed in a space between adjacent bit lines of the plurality of bit lines BL, and the landing pad LP may be formed on the buried contact BC. In a node separation process or a recess process for the landing pads LP, the landing pad hole LPH may be formed with a relatively large height since the etching selectivity between the metal material (e.g., tungsten) constituting the landing pads LP and the material (e.g., silicon nitride) constituting the adjacent bit line capping layers 138 or spacer 140 is low. In this case, the bit line capping layers 138 may need to be formed with a relatively large height so that exposure of the bit lines BL to the node separation process or the recess process may be reduced or prevented.

According to some embodiments, the buried contacts BC may be formed to have a relatively high top surface level and a large height in the vertical direction Z, and the intermediate conductive layers 160 may be formed as etch stop layers in the recess process or the node separation process for forming the landing pads LP. Accordingly, the landing pad hole LPH may be formed to have a relatively small height, the landing pad LP may be sufficiently separated from an adjacent landing pad LP, and the height of the bit line capping layers 138 in the vertical direction Z may also be reduced. According to some embodiments, the height of the bit line stack (e.g., the height of the bit line capping layers 138) may be reduced, and defects in the process for forming the landing pads LP may be reduced or prevented.

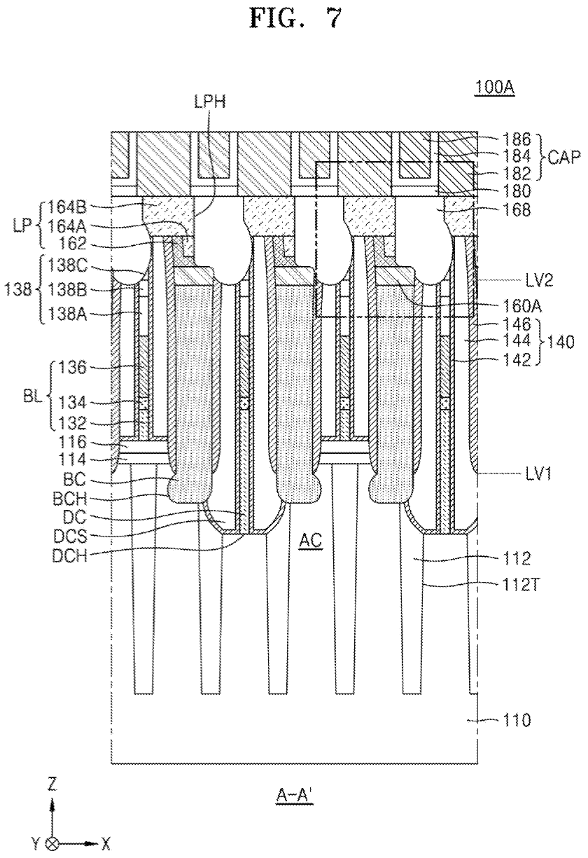

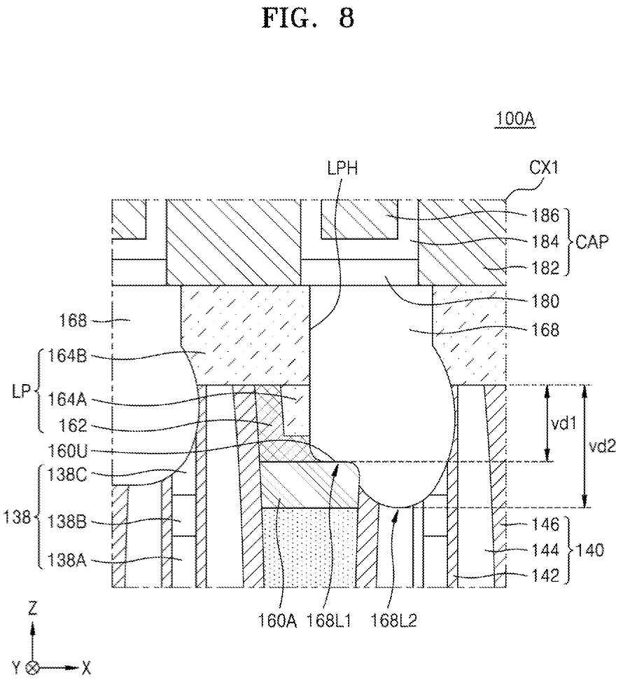

FIG. 7 is a cross-sectional view of a semiconductor device 100A according to some embodiments. FIG. 8 is an enlarged view of portion CX1 of FIG. 7.

Referring to FIG. 7 and FIG. 8, a top surface of the intermediate conductive layer 160A contacting the first bottom surface 168L1 of the insulating pattern 168 may have a flat top profile. For example, a first portion of the top surface of the intermediate conductive layer 160A may be covered by the landing pad LP, and a second portion of the top surface of the intermediate conductive layer 160A may be covered by the insulating pattern 168. The first portion of the top surface of the intermediate conductive layer 160A and the second portion of the top surface of the intermediate conductive layer 160A may be coplanar. For example, second portion of the top surface of the intermediate conductive layer 160A may have a flat top profile that is arranged on the same level as the first portion and is continuously arranged. In addition, the first bottom surface 168L1 of the insulating pattern 168 may be arranged at a level higher than the second bottom surface 168L2 of the insulating pattern 168.

In some embodiments, in the recess process or the node separation process for forming the landing pads LP, the intermediate conductive layer 160A may function as an etch stop layer. The etching rate of the intermediate conductive layer 160A may be lower than that of the landing pad LP in the recess process or the node separation process, and the intermediate conductive layer 160A may have a substantially flat top profile since the exposed surface of the intermediate conductive layer 160A may have a relatively low selectivity to the recess process or the node separation process.

Accordingly, the landing pad hole LPH may be formed having a relatively small height, the landing pad LP may be sufficiently separated from the adjacent landing pad LP, and the height of the bit line capping layers 138 may also be reduced. According to some embodiments, the height of the bit line stack (e.g., the height of the bit line capping layers 138) may be reduced, and defects in the process for forming the landing pads LP may be reduced or prevented.

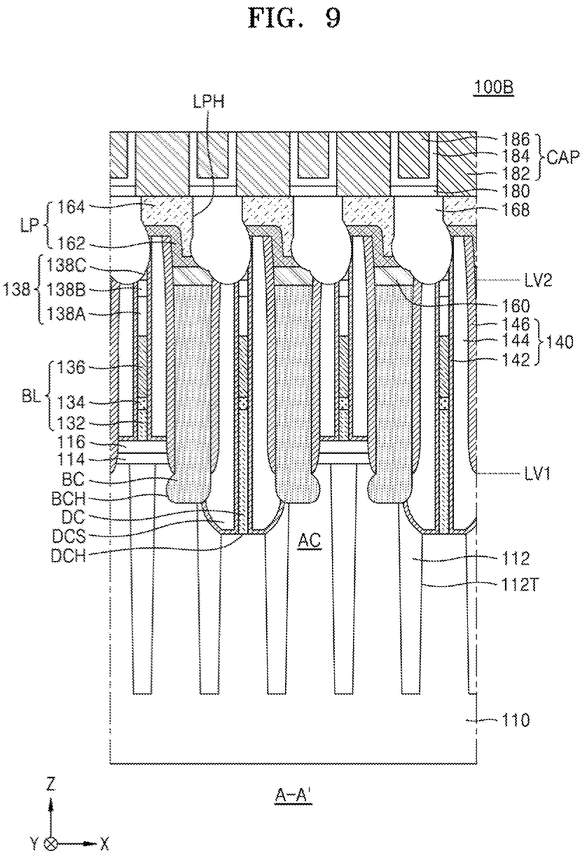

FIG. 9 is a cross-sectional view of a semiconductor device 100B according to some embodiments.

Referring to FIG. 9, the landing pad LP may include the landing pad barrier 162 and the landing pad conductive layer 164. The landing pad barrier 162 may be positioned between the landing pad conductive layer 164 and the intermediate conductive layer 160, between the landing pad conductive layer 164 and the bit line capping layer 138, and between the landing pad conductive layer 164 and the spacer 140.

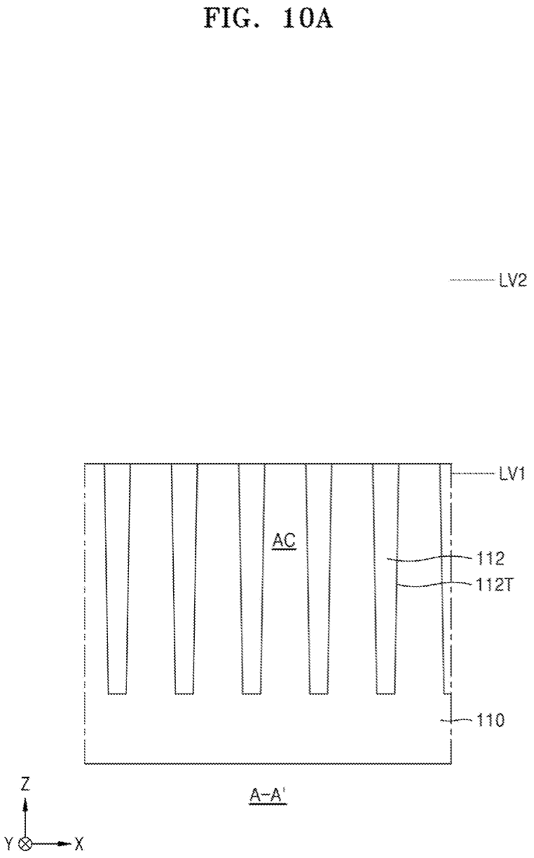

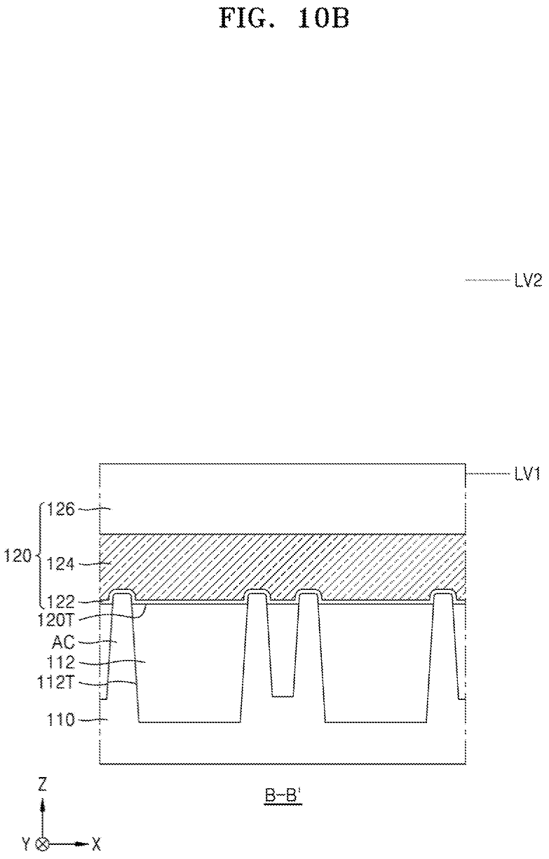

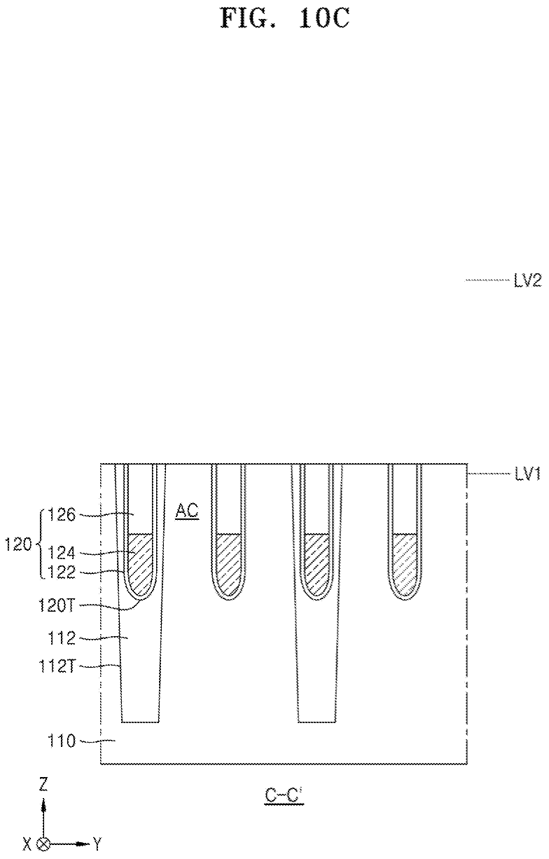

FIGS. 10A to 21C are cross-sectional views illustrating a method of manufacturing a semiconductor device 100 according to some embodiments. Specifically, FIGS. 10A, 11A, 12A, 13A, 14A, 15A, 16A, 17A, 18A, 19A, 20A, and 21A are cross-sectional views corresponding to section A-A′ of FIG. 2, and FIGS. 10B, 11B, 12B, 13B, 14B, 15B, 16B, 17B, 18B, 19B, 20B, and 21B are cross-sectional views corresponding to section B-B′ of FIG. 2, and FIGS. 10C, 11C, 12C, 13C, 14C, 15C, 16C, 17C, 18C, 19C, 20C, and 21C are cross-sectional views corresponding to section C-C′ of FIG. 2.

Referring to FIG. 10A, FIG. 10B, and FIG. 10C, the plurality of device separation trenches 112T may be formed in the cell array area MCA of the substrate 110.

Device separation layers 112 filling the plurality of device separation trenches 112T may be formed. A plurality of first active regions AC may be defined on the substrate 110 by forming the device separation layers 112 in the plurality of device separation trenches 112T. The plurality of first active regions AC may extend in the first oblique direction D1 (see FIG. 2) inclined at an angle with the first horizontal direction X1 and the second horizontal direction Y.

In some embodiments, the device separation layers 112 may be formed using silicon oxide, silicon nitride, silicon oxynitride, or a combination thereof. In some embodiments, the device separation layers 112 may have a double layer structure of a silicon oxide layer and a silicon nitride layer, but is not limited thereto.

A mask pattern (not shown) may be formed on the substrate 110 and a portion of the substrate 110 may be removed using the mask pattern as an etching mask to form the word line trench 120T. For example, the mask pattern for forming the word line trench 120T may be formed using a double patterning technique (DPT) or a quadruple patterning technique (QPT), but is not limited thereto.

The gate dielectric layer 122, the gate electrode 124, and the word line capping layer 126 may be sequentially formed in the word line trench 120T.

For example, the gate dielectric layer 122 may be conformally arranged on the inner wall of the word line trench 120T. The gate electrode 124 may be formed by depositing a conductive material (not shown) in the word line trench 120T and exposing an upper portion of the word line trench 120T, including the conductive material, and etching back an upper portion of the conductive layer in the word line trench 120T. For example, the conductive material may fill the word line trench 120T and be etched back, below the upper portion of the word line trench 120T.

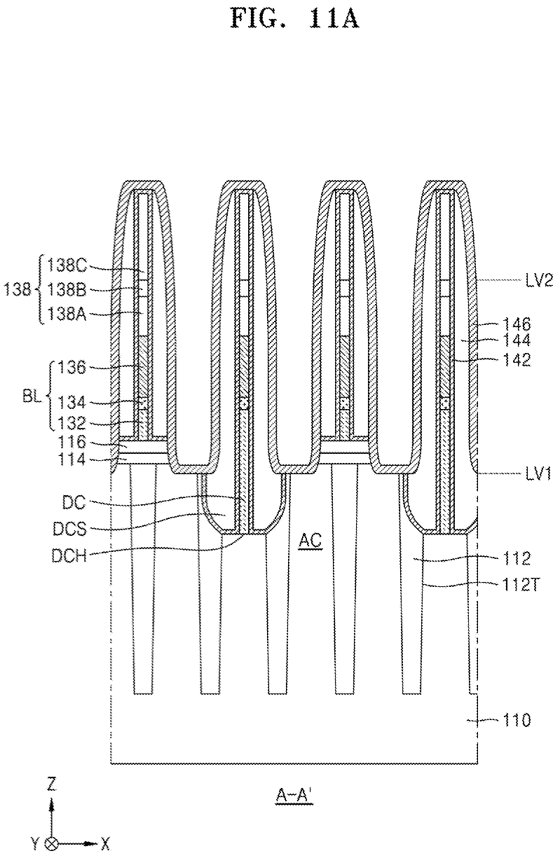

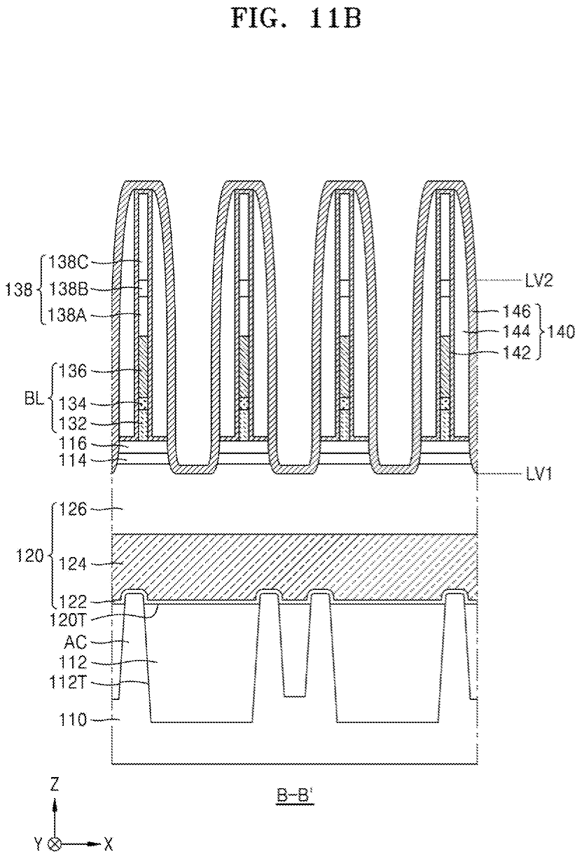

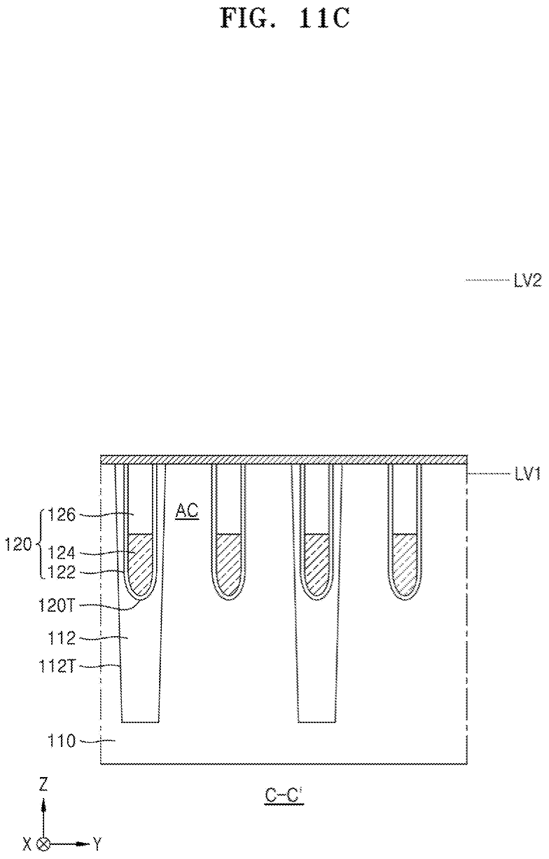

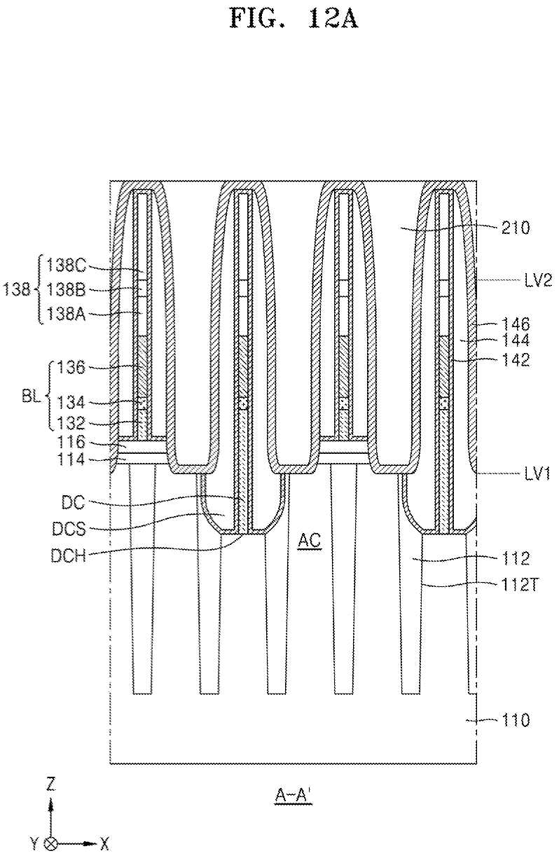

Referring to FIG. 11A, FIG. 11B, and FIG. 11C, the first buffer insulating layer 114 and the second buffer insulating layer 116 may be formed on the active region AC and the device separation layer 112. The conductive layer 132 may be formed on the first buffer insulating layer 114 and the second buffer insulating layer 116. Portions of the conductive layer 132, the first buffer insulating layer 114, the second buffer insulating layer 116, and the substrate 110 may be removed to form the bit line contact hole DCH. The bit line contact DC may be formed inside the bit line contact hole DCH.

The intermediate bit line conductive layer 134 and the bit line conductive layer 136 may be formed on the bit line contact DC and the conductive layer 132, and the bit line capping layer 138 may be formed on the bit line conductive layer 136. The bit line conductive layer 136, the intermediate bit line conductive layer 134, and the conductive layer 132 may be patterned using the bit line capping layer 138 as an etching mask to form the plurality of bit lines BL.

In some embodiments, the intermediate bit line conductive layer 134 may include at least one of TiN, TiSiN, CoSi, NiSi, or WSi. The bit line conductive layer 136 may include at least one of Ru, W, Co, Ti, or TiN.

The first spacer layer 142, the second spacer layer 144, and the third spacer layer 146 may be sequentially formed on the sidewalls of the bit line BL and the bit line capping layer 138. In some embodiments, the first spacer layer 142 and the third spacer layer 146 may include silicon nitride, and the second spacer layer 144 may include silicon oxide.

In some embodiments, the first spacer layer 142 and the second spacer layer 144 may be formed on the sidewalls of the bit line BL and the bit line capping layer 138, and the top surface of the first spacer layer 142 disposed on the top surface of the bit line capping layer 138 may be exposed. For example, the top surface of the first spacer layer 142 disposed on the top surface of the bit line capping layer 138 may be exposed by performing an anisotropic etching process on the second spacer layer 144, and the second spacer layer 144 may remain on the sidewall of the bit line capping layer 138. The third spacer layer 146 may be formed on the second spacer layer 144. The third spacer layer 146 may be formed on the top surface of the first spacer layer 142.

In some embodiments, in the process for forming the spacer 140, the bit line contact spacer DCS may be formed by depositing an insulating material in the bit line contact hole DCH. The bit line contact spacer DCS may include silicon oxide. The bit line contact spacer DCS may fill the inside of the bit line contact hole DCH. The first spacer layer 142 may extend into the bit line contact hole DCH and surround the sidewall of the bit line contact spacer DCS. The first spacer layer 142 may be disposed on a lower portion of the sidewall of the bit line contact spacer DCS.

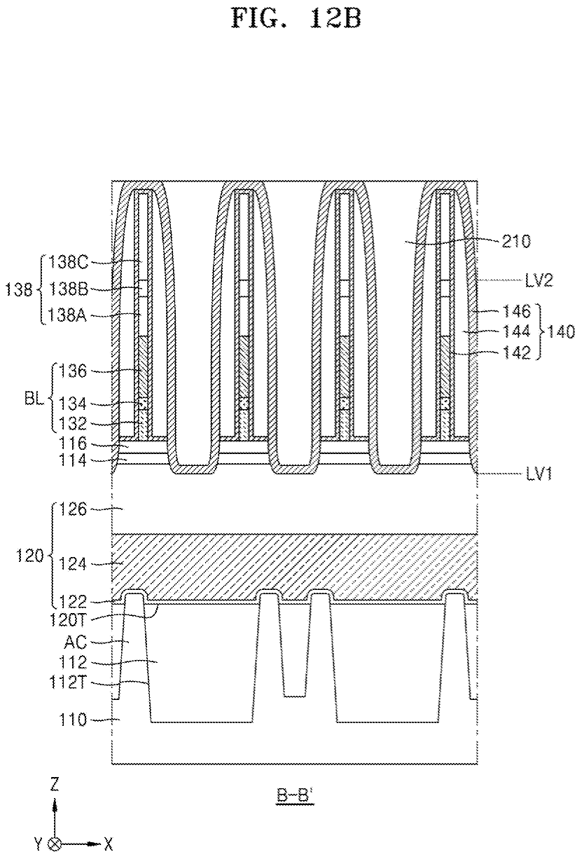

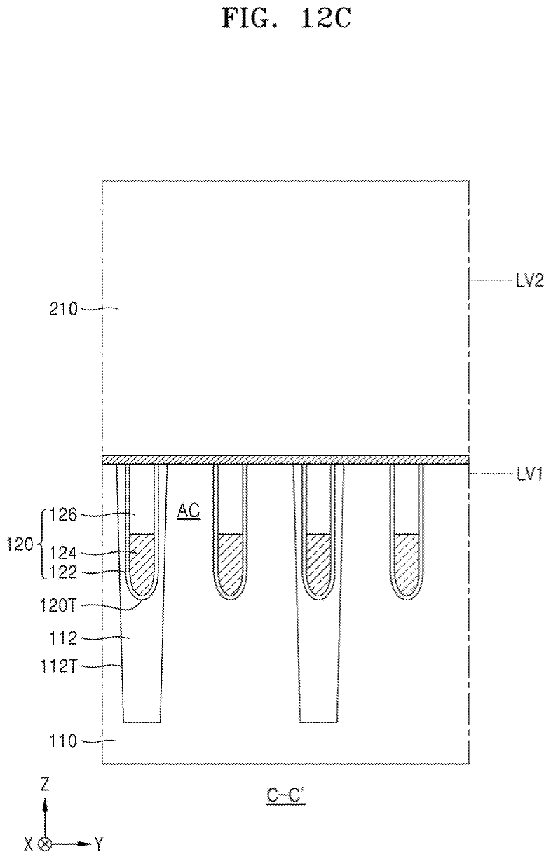

Referring to FIG. 12A, FIG. 12B, and FIG. 12C, a filling insulating layer 210 may be formed in a space between the plurality of bit lines BL. The filling insulating layer 210 may be formed using silicon oxide. The filling insulating layer 210 may be disposed in a shape of linear patterns extending in the second horizontal direction Y.

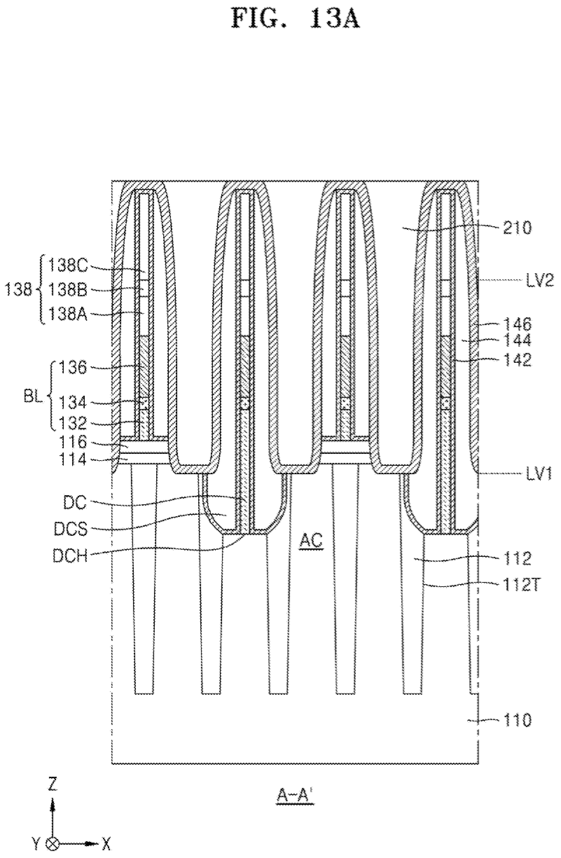

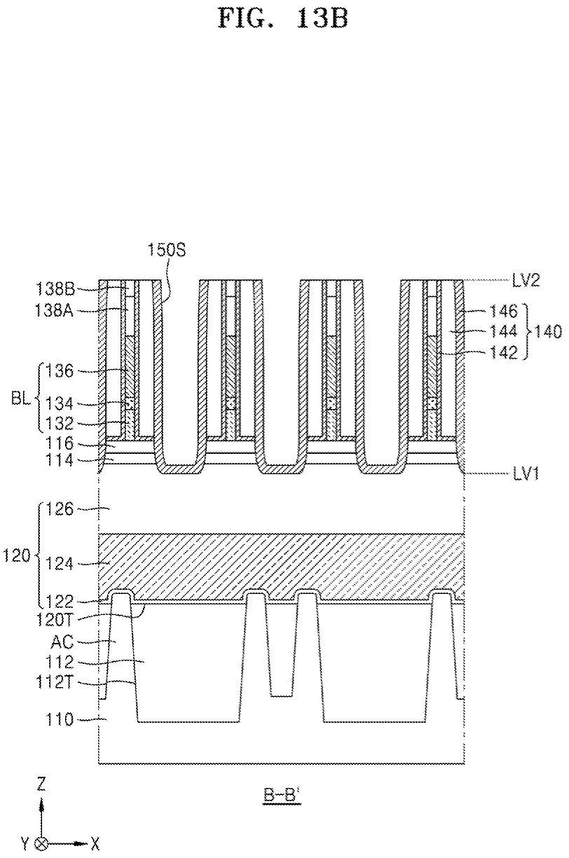

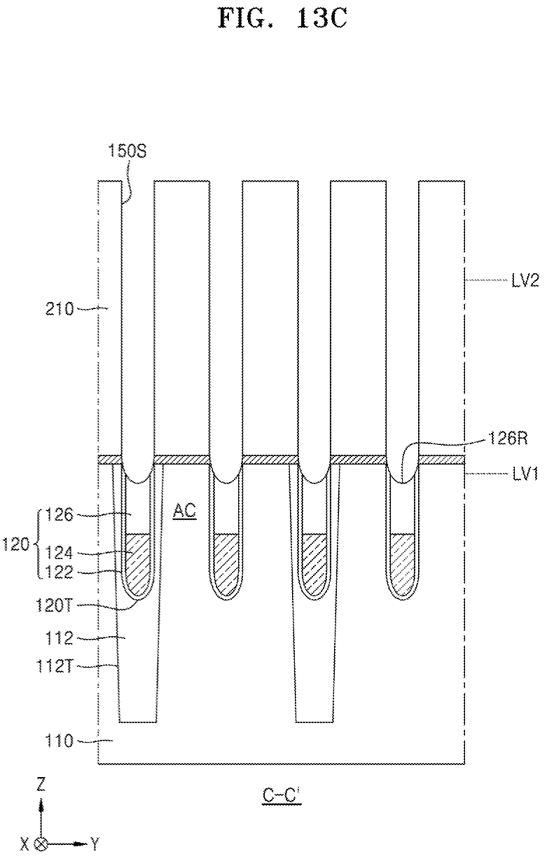

Referring to FIG. 13A, FIG. 13B, and FIG. 13C, a mask pattern (not shown) may be formed on the filling insulating layer 210 and the third spacer layer 146, and a portion of the filling insulating layer 210 may be removed using the mask pattern as an etching mask to form a fence space 150S. A portion of the word line capping layer 126 exposed to the bottom of the fence space 150S may be removed to form a recess 126R.

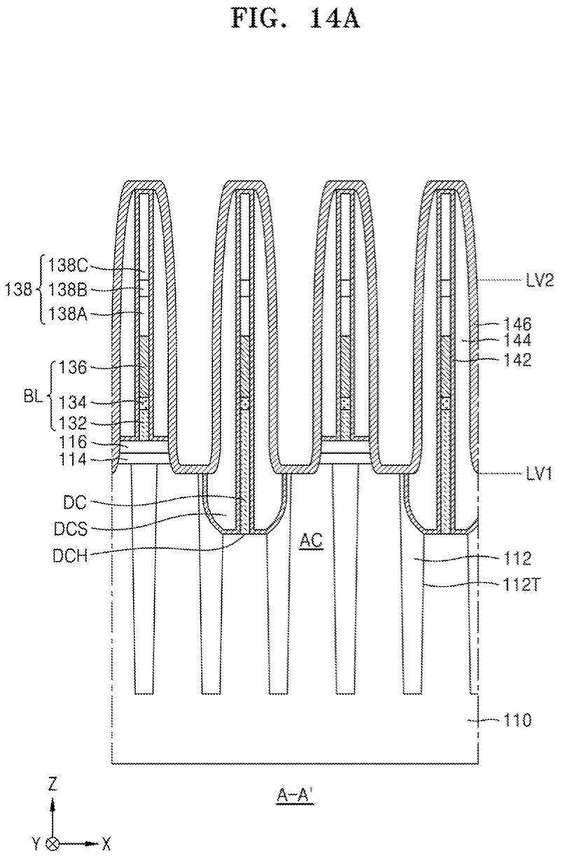

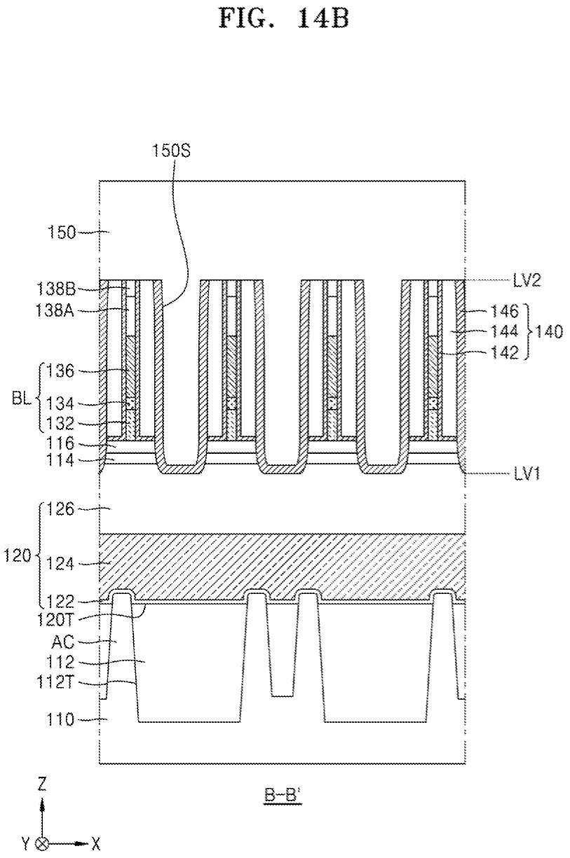

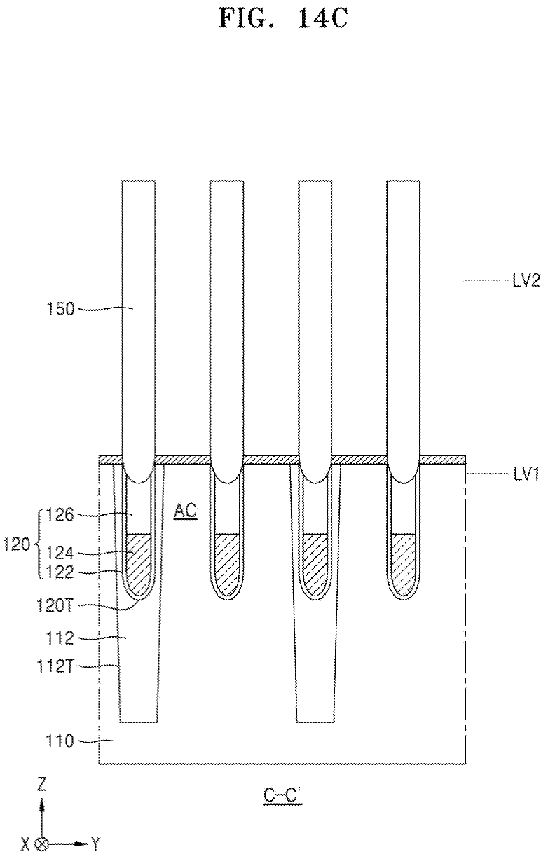

Referring to FIG. 14A, FIG. 14B, and FIG. 14C, an insulating layer (not shown) may be formed in the fence space 150S, and an upper portion of the insulating layer may be etched back to form the insulating fence 150 in the fence space 150S. A lower side of the insulating fence 150 may be arranged between two adjacent bit lines BL and fill the recess 126R of the word line capping layer 126. An upper side of the insulating fence 150 may be arranged to extend in the first horizontal direction X over the bit line BL and the bit line capping layer 138. In some embodiments, the insulating fence 150 may be formed using silicon nitride.

Remaining portions of the filling insulating layer 210 may be removed following the formation of the insulating fence 150.

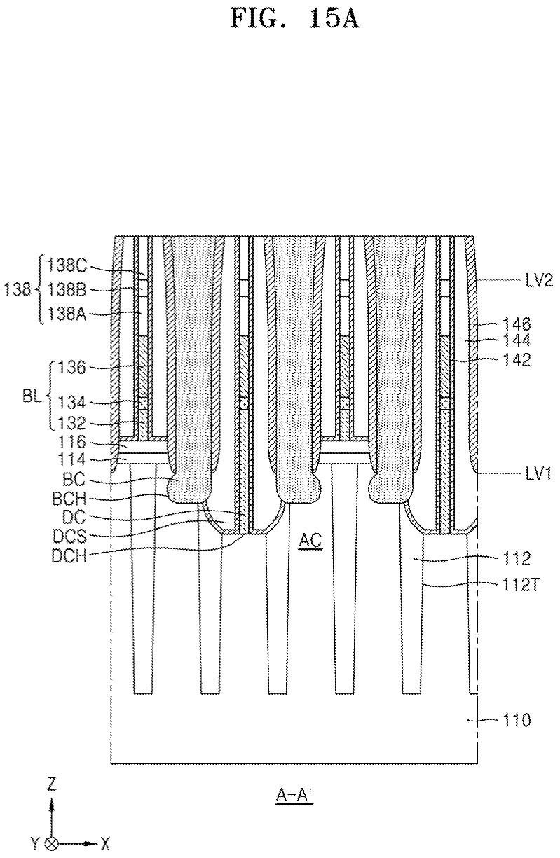

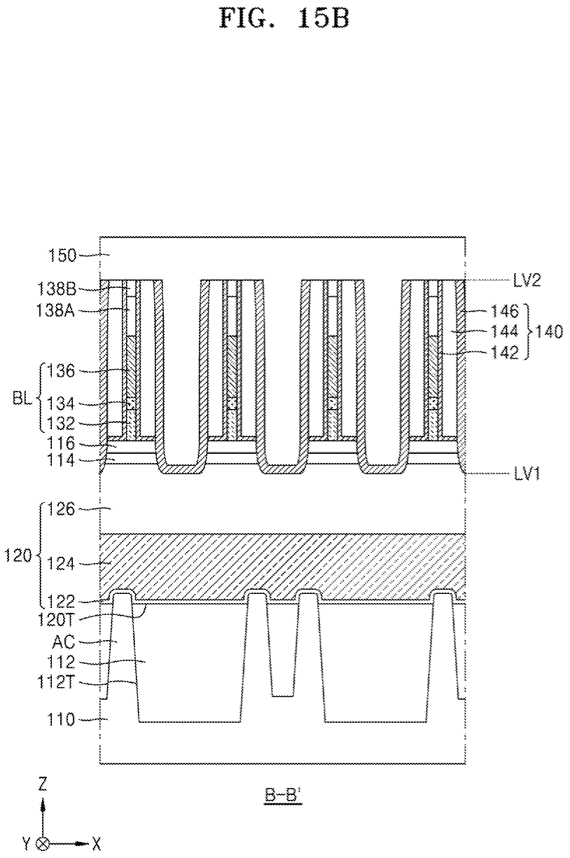

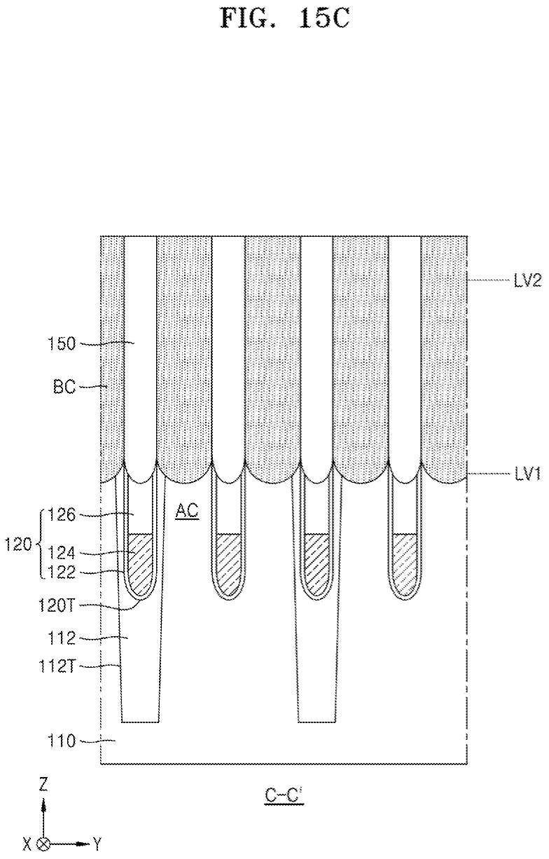

Referring to FIG. 15A, FIG. 15B, and FIG. 15C, the buried contact hole BCH may be formed by removing an upper portion of the substrate 110 exposed between adjacent bit lines BL and between adjacent insulating fences 150. In some embodiments, a process for forming the buried contact hole BCH may include a wet etching process, a dry etching process, or a combination thereof.

The buried contact BC inside of the buried contact hole BCH may be formed. The buried contact BC may be formed between adjacent bit lines BL and between adjacent insulating fences 150 and may be formed in a pillar shape extending in the vertical direction Z. The plurality of buried contacts BC may be spaced apart from each other in the first horizontal direction X and the second horizontal direction Y, and may be connected to the top portions of the active regions AC. The bottom surfaces of the buried contacts BC contacting the active regions AC may have a rounded shape. In some embodiments, the buried contacts BC may include doped polysilicon.

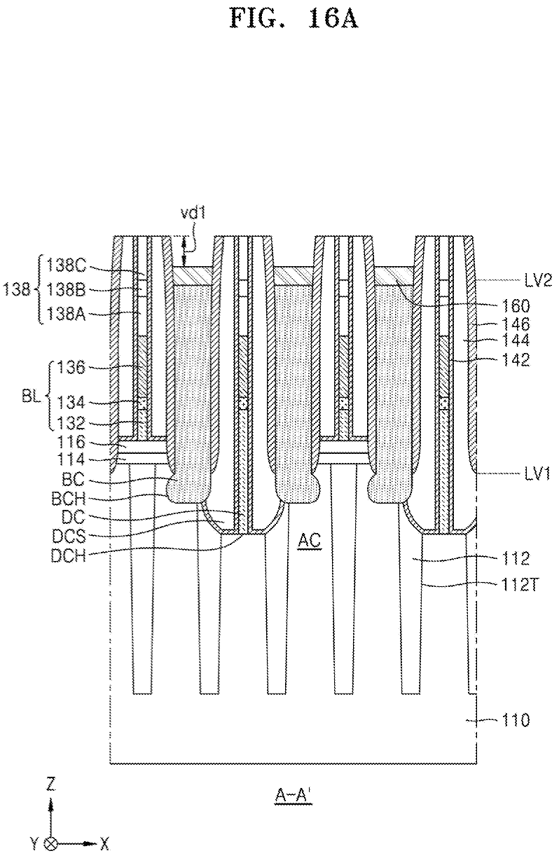

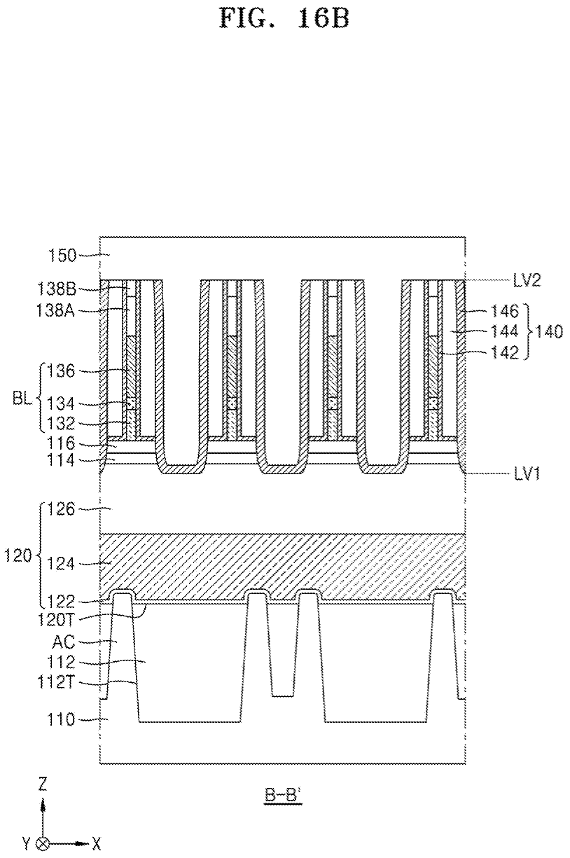

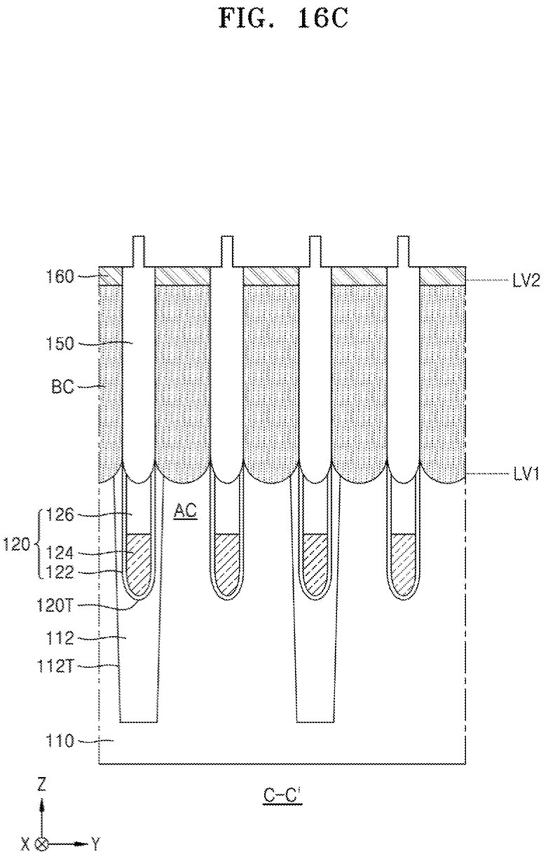

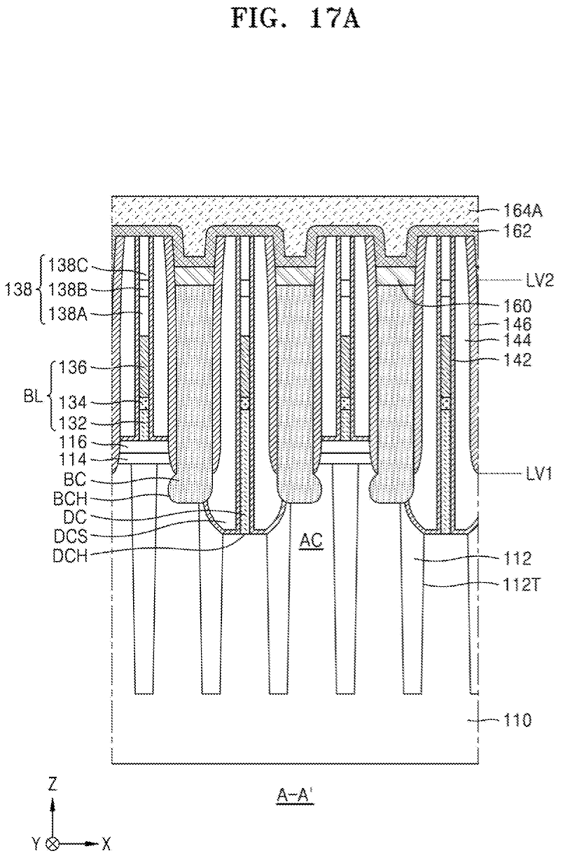

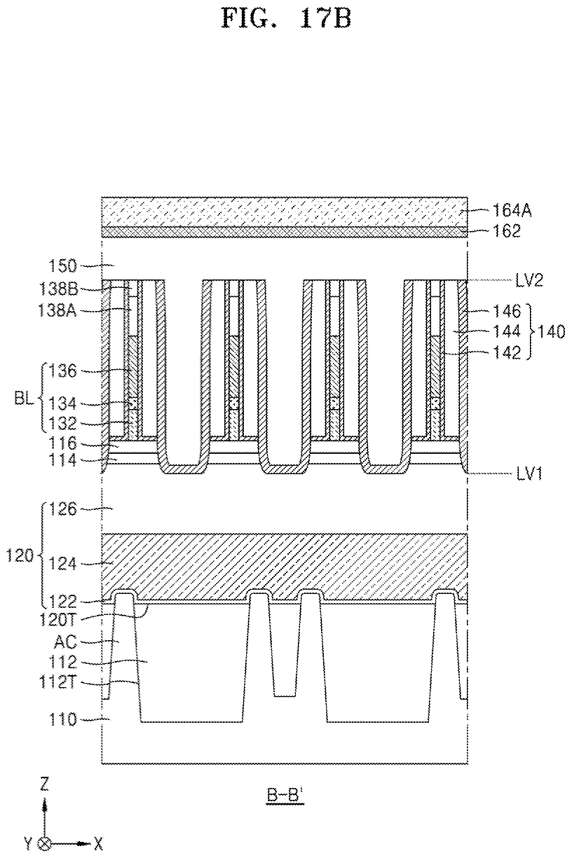

Referring to FIG. 16A, FIG. 16B, and FIG. 16C, an etch-back process may be performed on upper sides of the buried contacts BC. The etch-back process may lower the height of the plurality of buried contacts BC. The etch-back process may remove an upper portion of the plurality of buried contacts BC. The plurality of buried contacts BC may have top surfaces arranged at a level lower than top surfaces of the plurality of insulation fences 150.

In some embodiments, in the etch-back process, a portion of the side of the insulating fence 150 may be removed to narrow a width of an upper portion of the insulating fence 150. In some embodiments, after the etch-back process lowering the height of the top surface of the buried contact BC, an additional recess process for removing a portion of the side of the insulating fence 150 may be further performed.

The intermediate conductive layers 160 may be formed on exposed top surfaces of the plurality of buried contacts BC. The intermediate conductive layers 160 may be formed on exposed top surfaces of the plurality of buried contacts BC after the width of the upper portion of the insulating fence 150 has been narrowed. In some embodiments, the intermediate conductive layers 160 may include a metal silicide. The metal silicide may include at least one of cobalt silicide (CoSi), nickel silicide (NiSi), or tungsten silicide (WSi).

In some embodiments, the etch-back process for lowering the height of the top surface of the buried contact BC may be performed so that the top surface of the buried contact BC is disposed at a relatively high level, for example, so that the top surface of the intermediate conductive layer 160 arranged on the buried contact BC may be spaced apart from the top surface of the bit line capping layer 138 by a relatively small first vertical distance vd1. The first vertical distance vd1 may be in the range of about 5 to 50 nm.

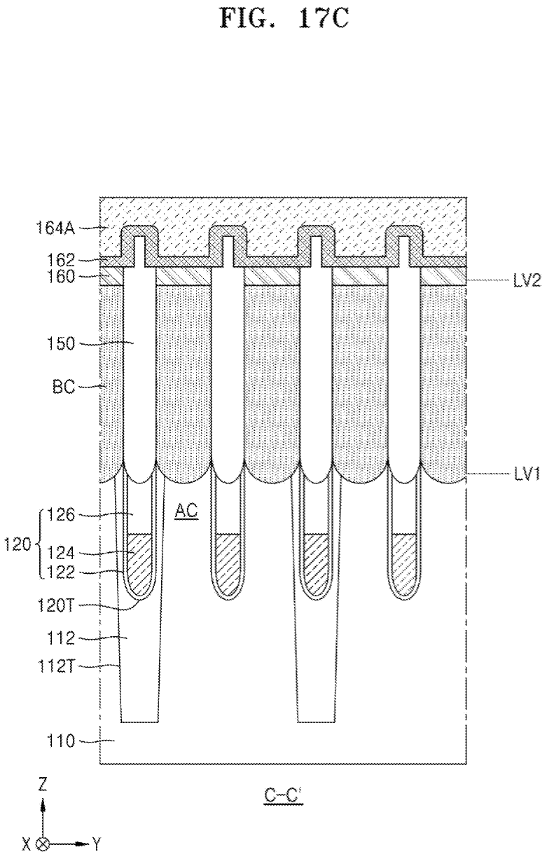

Referring to FIG. 17A, FIG. 17B, and FIG. 17C, the landing pad barrier 162 and the first landing pad conductive layer 164A may be sequentially formed on the intermediate conductive layer 160. For example, the landing pad barrier 162 may be formed directly on exposed portions of the spacer 140, the insulating fence 150, and the intermediate conductive layer 160, and the first landing pad conductive layer 164A may be formed on the landing pad barrier 162. In some embodiments, the landing pad barrier 162 may be formed using at least one of Ti, TiN, Ta, TaN, Ru, or RuN. In some embodiments, the first landing pad conductive layer 164A may be formed using at least one of W, aluminum (Al), Ta, Co, CoN, TiN, molybdenum (Mo), or MoN.

In some embodiments, the top surfaces of the intermediate conductive layers 160 may be spaced apart from the top surfaces of the bit line capping layers 138 by the first distance vd1 (see FIG. 16A), which may be a relatively small distance, and the aspect ratio of the space may be reduced in the process forming the landing pad barrier 162 and the first landing pad conductive layer 164A. For example, the space between adjacent bit line capping layers 138 and between adjacent insulating fences 150 may be completely filled with a metal material without voids.

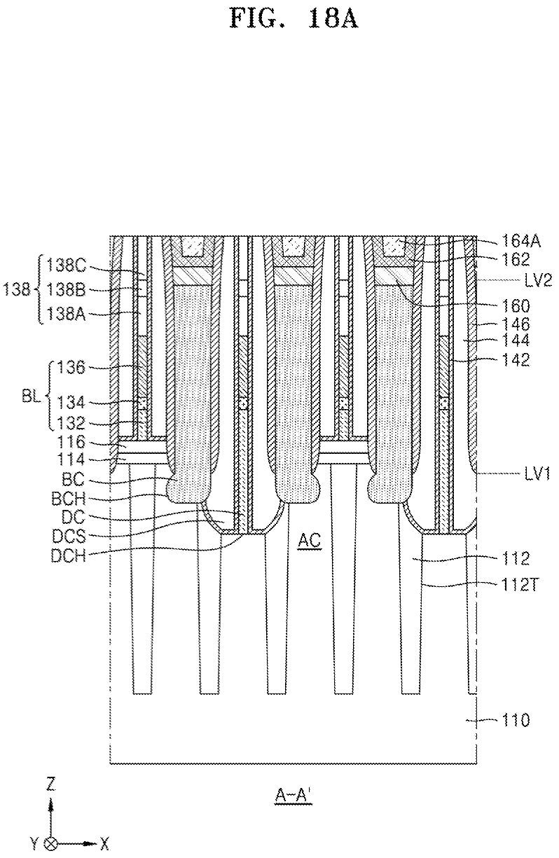

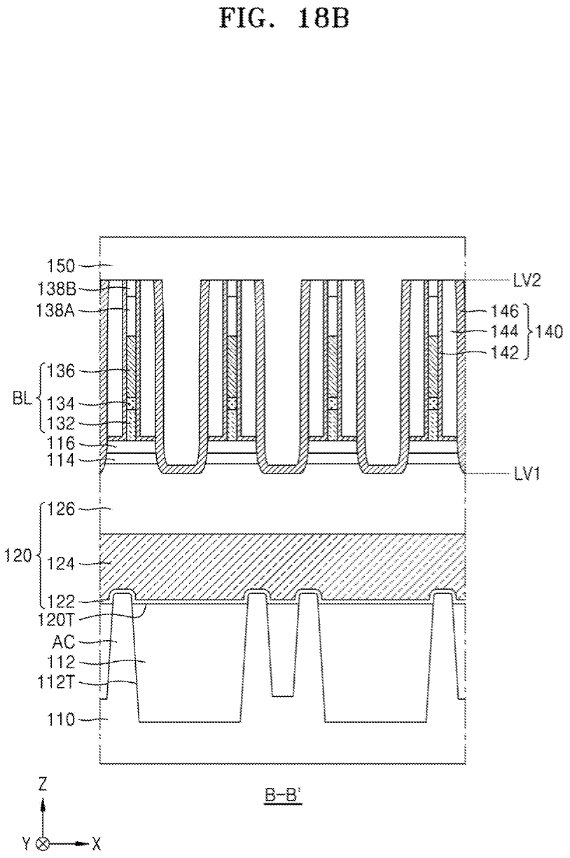

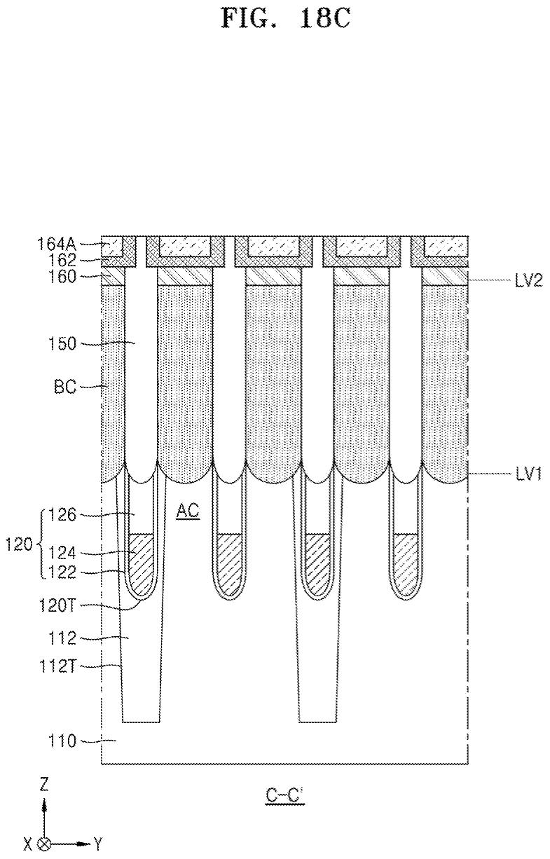

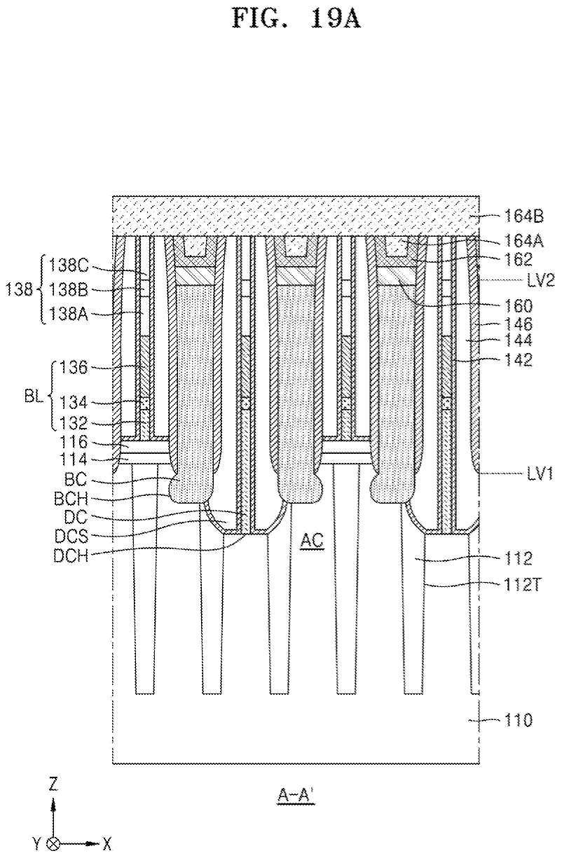

Referring to FIG. 18A, FIG. 18B, and FIG. 18C, the upper portions of the landing pad barrier 162 and the first landing pad conductive layer 164A may be removed by performing an etch-back process. The etch-back process may expose the top surfaces of the bit line capping layer 138 and the insulating fence 150.

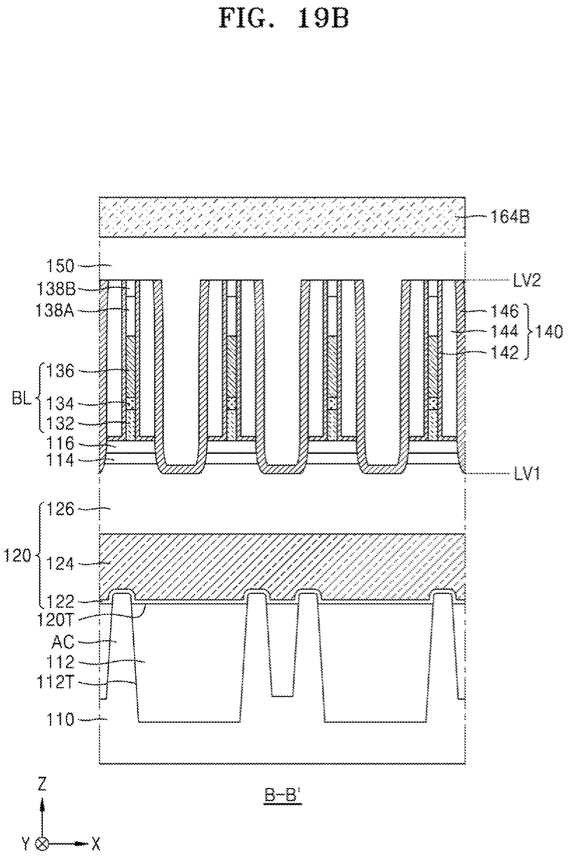

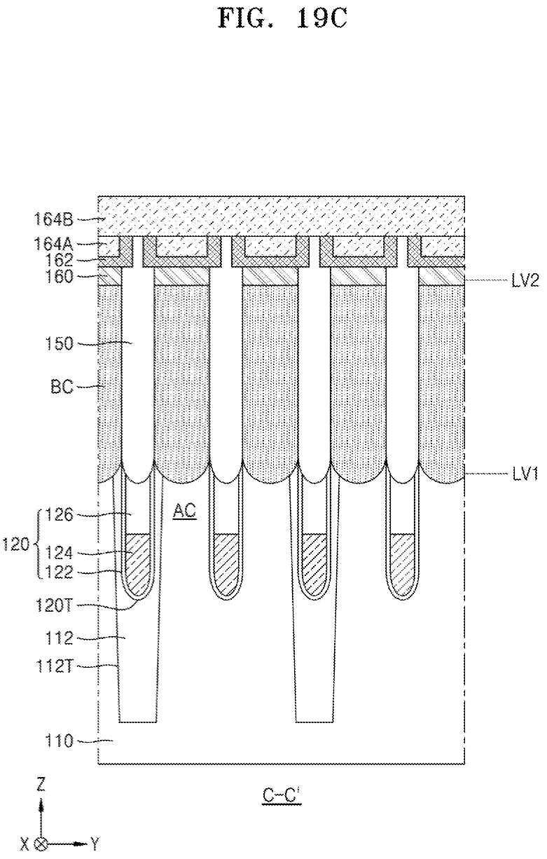

Referring to FIG. 19A, FIG. 19B, and FIG. 19C, the second landing pad conductive layer 164B may be formed on the bit line capping layer 138, the insulating fence 150, and the first landing pad conductive layer 164A.

In some embodiments, the second landing pad conductive layer 164B may be formed using at least one of W, Al, Ta, Co, CoN, TiN, Mo, or MoN. In some embodiments, the second landing pad conductive layer 164B may be formed using the same material as the first landing pad conductive layer 164A. In some embodiments, the second landing pad conductive layer 164B may be formed using a material different than that of the first landing pad conductive layer 164A.

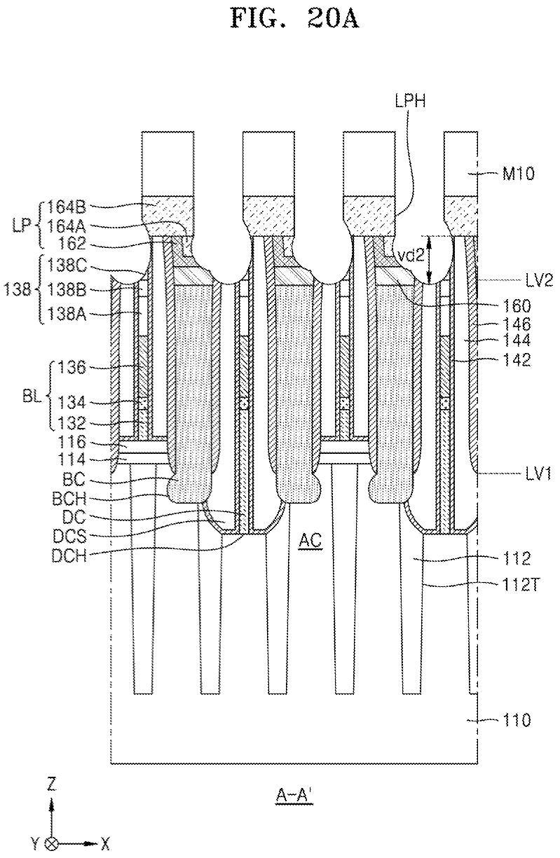

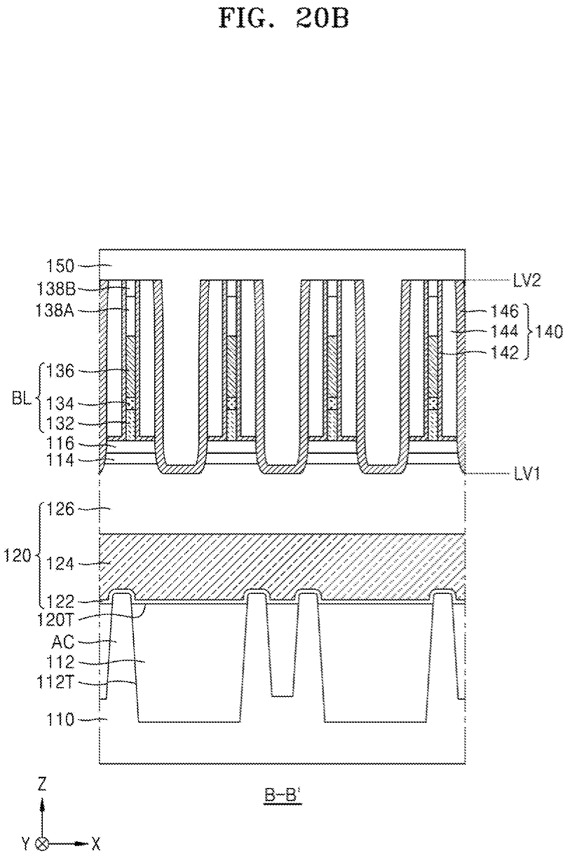

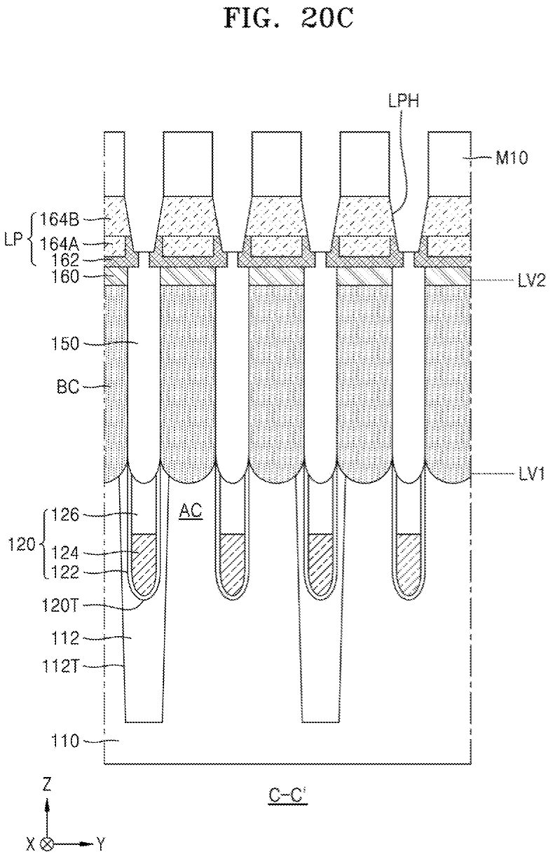

Referring to FIG. 20A, FIG. 20B, FIG. 20C, a mask pattern M10 may be formed on the second landing pad conductive layer 164B, and landing pads LP may be formed by removing parts of the landing pad barrier 162, the first landing pad conductive layer 164A, and the second landing pad conductive layer 164B using the mask pattern M10 as an etching mask.

In some embodiments, the mask pattern M10 may have a shape of a plurality of island-shaped patterns spaced apart from each other. When portions of the landing pad barrier 162, the first landing pad conductive layer 164A, and the second landing pad conductive layer 164B are removed in the process for forming the landing pad LP, portions of the bit line capping layer 138 and the spacer 140 not covered by the mask pattern M10 may also be removed, and a landing pad hole LPH may be formed where portions of the landing pad barrier 162, the first landing pad conductive layer 164A, the second landing pad conductive layer 164B, the bit line capping layer 138, and the spacer 140 are removed.

In some embodiments, the process for forming the landing pad LP may include a selective etching process. The selective etching process may use an etchant having an etching selectivity with the intermediate conductive layer 160, for example, wherein in the process for forming the landing pad LP, the top surface of the intermediate conductive layer 160 exposed to the bottom portion of the landing pad hole LPH may function as an etch stop layer. After the intermediate conductive layer 160 is exposed to the bottom portion of the landing pad hole LPH, the exposed intermediate conductive layer 160 may be removed at a relatively low etching rate.

For example, the etching rate of the first landing pad conductive layer 164A and the second landing pad conductive layer 164B in the selective etching process may be significantly higher than that of the intermediate conductive layer 160, and the etching rate of the landing pad barrier 162 in the selective etching process may be significantly higher than that of the intermediate conductive layer 160. In some embodiments, a ratio of the etching rate of the intermediate conductive layer 160 to the etching rate of the first landing pad conductive layer 164A may be in the range of about 3:1 to about 100:1, for example, in the range of about 5:1 to about 10:1 or in the range of about 10:1 to about 20:1.

As the intermediate conductive layer 160 may function as an etch stop layer, the landing pad LP may be completely separated from the adjacent landing pad LP, and node separation failure (e.g., bad bridge or short circuit between landing pads LP due to unetched metal layer) in which the landing pad LP is insufficiently separated from the adjacent landing pad LP may be prevented.

In some embodiments, in the selective etching process, the etching rate of the bit line capping layer 138 or the spacer 140 may be higher than the etching rate of the intermediate conductive layer 160, where, as shown in FIG. 20A, the top surface of the spacer 140 exposed to the bottom portion of the landing pad hole LPH may be disposed at a vertical level lower than the top surface of the intermediate conductive layer 160 exposed to the bottom portion of the landing pad hole LPH. The top surface of the spacer 140 exposed to the bottom portion of the landing pad hole LPH may be spaced apart from the top surface of the bit line capping layer 138 by a second vertical distance vd2. The second vertical distance vd2 may be in range from about 5 nm to about 30 nm.

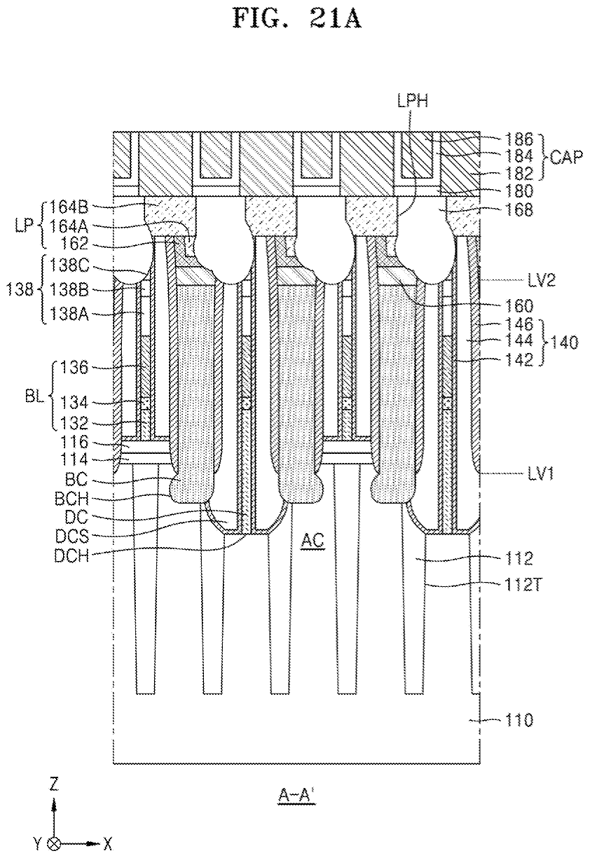

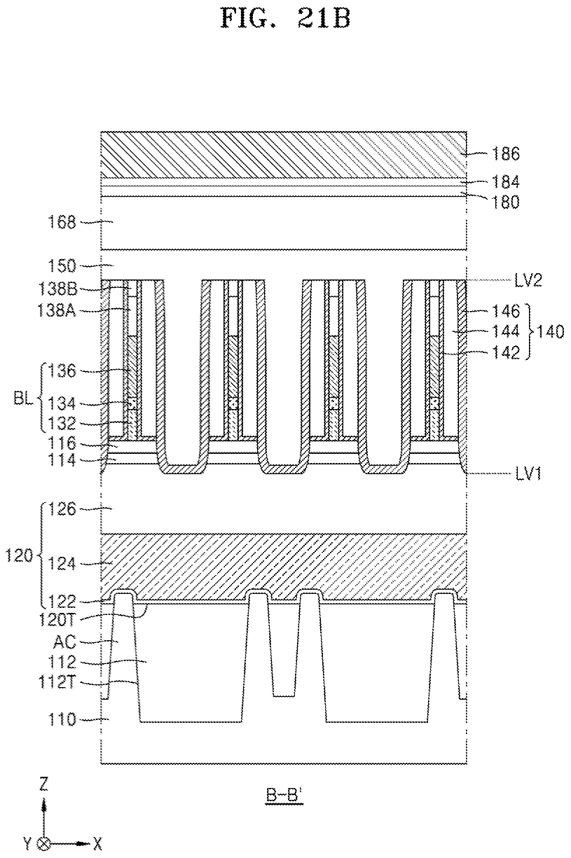

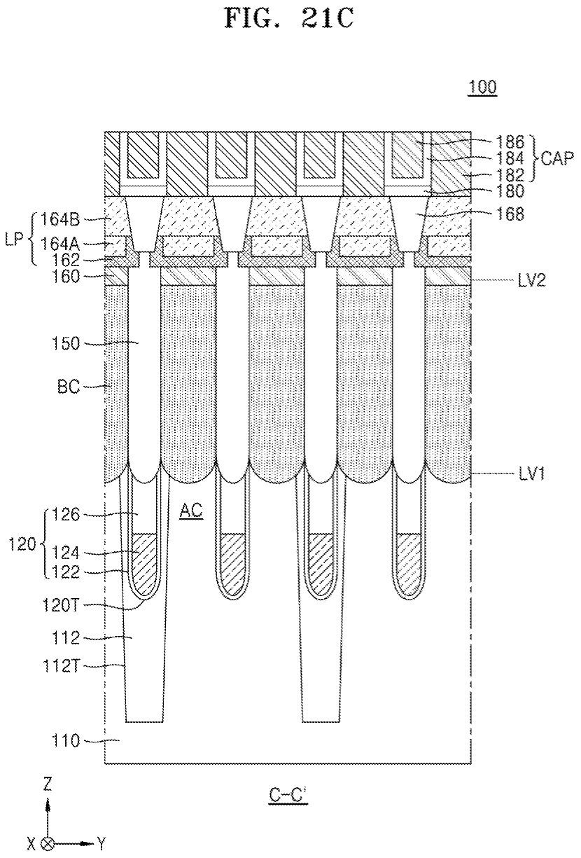

Referring to FIG. 21A, FIG. 21B, FIG. 21C, the insulating pattern 168 covering sidewalls of the plurality of landing pads LP may be formed in the landing pad hole LPH. The insulating pattern 168 may contact the exposed surface of the intermediate conductive layer 160. The insulating pattern 168 may be physically separated from the buried contact BC. The insulating pattern 168 may be formed using at least one of silicon nitride, silicon oxide, or silicon oxynitride.

The plurality of lower electrodes 182 connected to the landing pads LP and extending in the vertical direction Z may be formed. The capacitor dielectric layer 184 and the upper electrode 186 may be sequentially formed on sidewalls of the plurality of lower electrodes 182. For example, the capacitor dielectric layer 184 may be formed on sidewalls of the plurality of lower electrodes 182, and the upper electrode 186 may be formed on the capacitor dielectric layer 184.

The semiconductor device 100 may be completed by performing methods described herein.

In some embodiments, the buried contact BC having a top surface disposed at a relatively high level may be formed, and the landing pad LP may be formed by a selective etching process using the intermediate conductive layer 160 as an etch stop layer. In some embodiments, the height of the landing pad LP formed by using a recess process for node separation of the landing pads LP may be reduced, and the height of the bit line capping layer 138 may be reduced to improve a precision of the landing pad LP forming process.

While the inventive concept has been particularly shown and described with reference to embodiments thereof, it will be understood that various changes in form and details may be made therein without departing from the spirit and scope of the following claims.

What is claimed is:

1. A semiconductor device comprising:
a substrate including an active region defined by a device separation layer;
a plurality of bit lines disposed on the substrate;
a buried contact disposed on the substrate between adjacent bit lines among the plurality of bit lines and connected to the active region;
an intermediate conductive layer disposed on the buried contact;
a landing pad disposed on the intermediate conductive layer; and
an insulating pattern disposed on a sidewall of the landing pad and contacting at least a portion of a top surface of the intermediate conductive layer.

2. The semiconductor device of claim 1, wherein an entirety of a top surface of the buried contact is covered by the intermediate conductive layer, and
the buried contact are physically separated from the insulating pattern.

3. The semiconductor device of claim 1, further comprising:
a plurality of bit line capping layers arranged on the plurality of bit lines, respectively; and
a spacer arranged on a sidewall of each of the plurality of bit lines;
wherein a bottom surface of the insulating pattern is arranged at a level lower than a top surface of the plurality of bit line capping layers.

4. The semiconductor device of claim 3, wherein an upper side of the insulating pattern surrounds the sidewall of the landing pad, and
a lower side of the insulating pattern includes a rounded bottom surface contacting the plurality of bit line capping layers and the spacer.

5. The semiconductor device of claim 3, wherein a first bottom surface of the insulating pattern in contact with the top surface of the intermediate conductive layer is arranged at a level higher than a second bottom surface of the insulating pattern in contact with the spacer.

6. The semiconductor device of claim 5, wherein a second bottom surface of the insulating pattern has a vertical distance of 5 nanometers to 20 nanometers from the top surface of the plurality of bit line capping layers.

7. The semiconductor device of claim 3, wherein the insulating pattern surrounds the sidewall of the landing pad and the top surface of the intermediate conductive layer in contact with the insulating pattern includes a shoulder portion.

8. The semiconductor device of claim 3, wherein the insulating pattern surrounds the sidewall of the landing pad and the top surface of the intermediate conductive layer in contact with the insulating pattern has a flat profile portion.

9. The semiconductor device of claim 1, wherein the intermediate conductive layer is formed of a metal silicide and includes at least one of cobalt silicide, nickel silicide, and tungsten silicide.

10. The semiconductor device of claim 1, wherein a bottom surface of the intermediate conductive layer is arranged at a level higher than a top surface of the plurality of bit lines.

11. A semiconductor device comprising:
a substrate including a plurality of active regions defined by a plurality of device separation layers;
a plurality of bit lines disposed on the substrate;
a plurality of bit line capping layers arranged on the plurality of bit lines;
a plurality of buried contacts disposed on the substrate between adjacent bit lines among the plurality of bit lines, extending in a vertical direction, and connected to the plurality of active regions;
a plurality of intermediate conductive layers disposed on the plurality of buried contacts, respectively, having bottom surfaces disposed at a level higher than top surfaces of the plurality of bit lines;
a plurality of landing pads disposed on the plurality of intermediate conductive layers; and
an insulating pattern disposed on a sidewall of each of the plurality of landing pads and contacting at least a portion of a top surface of each of the plurality of intermediate conductive layers.

12. The semiconductor device of claim 11, wherein an entirety of a top surface of each of the plurality of buried contacts is covered by a respective one of the plurality of intermediate conductive layers, and
the plurality of buried contacts are physically separated from the insulating pattern.

13. The semiconductor device of claim 11, wherein a bottom surface of the insulating pattern is disposed at a level lower than a top surface of the plurality of bit line capping layers.

14. The semiconductor device of claim 11, wherein an upper portion of the insulating pattern surrounds a sidewall of the plurality of landing pads, and
a lower portion of the insulating pattern includes a rounded bottom surface contacting each of the plurality of bit line capping layers.

15. The semiconductor device of claim 11, wherein a first bottom surface of the insulating pattern contacting the top surface of each of the plurality of intermediate conductive layers is disposed at a level higher than a lowermost surface of the insulating pattern.

16. The semiconductor device of claim 15, wherein the lowermost surface of the insulating pattern has a vertical distance between about 5 nanometers to 20 nanometers from a top surface of the plurality of bit line capping layers.

17. The semiconductor device of claim 11, wherein the plurality of intermediate conductive layers is formed of a metal silicide and includes at least one of cobalt silicide, nickel silicide, and tungsten silicide.

18. A semiconductor device comprising:
a substrate including a plurality of active regions defined by a plurality of device separation layers;
a plurality of bit lines extending in a first horizontal direction on the substrate;
a plurality of bit line capping layers disposed on the plurality of bit lines, respectively;
a plurality of spacers arranged on sidewalls of the plurality of bit lines;
a word line extending in a second horizontal direction in the substrate and perpendicular to the first horizontal direction;
a plurality of buried contacts disposed on the substrate between adjacent bit lines among the plurality of bit lines and connected to the plurality of active regions;
a plurality of intermediate conductive layers disposed on the plurality of buried contacts, respectively, and including a metal silicide;
a plurality of landing pads disposed on the plurality of intermediate conductive layers;
an insulating pattern surrounding a sidewall of each of the plurality of landing pads and contacting at least a portion of a top surface of each of the plurality of intermediate conductive layers;
a plurality of lower electrodes disposed on the plurality of landing pads, respectively;
a capacitor dielectric layer disposed on the insulating pattern and on sidewalls of the plurality of lower electrodes; and
an upper electrode disposed on the capacitor dielectric layer.

19. The semiconductor device of claim 18, wherein a lowermost surface of the insulating pattern has a vertical distance between about 5 nanometers to 20 nanometers from a top surface of the plurality of bit line capping layers.

20. The semiconductor device of claim 18, wherein an upper portion of the insulating pattern surrounds the sidewall of each of the plurality of landing pads, and
a lower side of the insulating pattern includes a rounded bottom surfaces contacting each of the plurality of bit line capping layers.
